(19) United States
(12) Patent Application Publication
(10) Pub. No.: US 2025/0241078 A1
(43) Pub. Date: Jul. 24, 2025

(54) IMAGE SENSOR

(71) Applicant: SAMSUNG ELECTRONICS CO., LTD., Suwon-si (KR)

(72) Inventor: Takayuki Ogasahara, Yokohama (JP)

(73) Assignee: SAMSUNG ELECTRONICS CO., LTD., Suwon-si (KR)

(21) Appl. No.: 19/022,279

(22) Filed: Jan. 15, 2025

(30) Foreign Application Priority Data
Jan. 19, 2024 (JP) 2024-006508
Oct. 29, 2024 (KR) 10-2024-0149922

(51) Int. Cl. H10F 39/00; H10F 39/18

(52) U.S. Cl. CPC H10F 39/806; H10F 39/182; H10F 39/805; H10F 39/8053

(57) ABSTRACT

Provided is an image sensor including: a first grayscale pixel including a first photoelectric converter and a first light collector configured to allow light of a first wavelength range to be collected in the first photoelectric converter; a detection pixel adjacent to the first grayscale pixel, the detection pixel including a detection photoelectric converter and a detection circuit configured to detect a variation of an amount of light incident on the detection photoelectric converter over time; a high refractive region including a first refractive index; and a low refractive region including a second refractive index, wherein the second refractive index is less than the first refractive index, and wherein the high refractive region and the low refractive region are in the first light collector and are arranged in a first pattern.

### CROSS-REFERENCE TO RELATED APPLICATION

This application claims priority to Japanese Patent Application No. 2024-006508, filed in the Japanese Patent Office on Jan. 19, 2024, and Korean Patent Application No. 10-2024-0149922, filed in the Korean Intellectual Property Office on Oct. 29, 2024, the disclosures of which are incorporated by reference herein in their entireties.

### BACKGROUND

The disclosure relates to an image sensor.

Image sensors perform photoelectric conversion on incident light to generate an electrical signal. Recently, image sensors, which include a grayscale pixel generating an electrical signal from the amount of received light and a detection pixel detecting a time variation of the amount of received light, are being developed. In some examples, the grayscale pixel and the detection pixel may be disposed in one semiconductor chip.

When the grayscale pixel and the detection pixel are disposed in one semiconductor chip, the amount of received light in the grayscale pixel may be reduced compared to a case where only the grayscale pixel is disposed in one semiconductor chip. Therefore, in image sensors where the grayscale pixel and the detection pixel are disposed in one semiconductor chip, it may be required to prevent a reduction in the amount of received light in the grayscale pixel.

### SUMMARY

Provided is an image sensor which may prevent a reduction in the amount of received light in a grayscale pixel.

According to an aspect of the disclosure, an image sensor includes: a first grayscale pixel including a first photoelectric converter and a first light collector configured to allow light of a first wavelength range to be collected in the first photoelectric converter; a detection pixel adjacent to the first grayscale pixel, the detection pixel including a detection photoelectric converter and a detection circuit configured to detect a variation of an amount of light incident on the detection photoelectric converter over time; a high refractive region including a first refractive index; and a low refractive region including a second refractive index, wherein the second refractive index is less than the first refractive index, and wherein the high refractive region and the low refractive region are in the first light collector and are arranged in a first pattern.

According to an aspect of the disclose, an image sensor includes: a first grayscale pixel; a second grayscale pixel; a third grayscale pixel; and a detection pixel adjacent to the first grayscale pixel, the second grayscale pixel, and the third grayscale pixel, wherein the first grayscale pixel includes a first light collector configured to allow light of a first wavelength range to be collected in a first photoelectric converter, wherein the second grayscale pixel includes a second light collector configured to allow light of a second wavelength range to be collected in a second photoelectric converter, wherein the third grayscale pixel includes a third light collector configured to allow light of a third wavelength range to be collected in a third photoelectric converter, and wherein each of the first light collector, the second light collector, and the third light collector includes a high refractive region and a low refractive region arranged in a certain pattern and having a refractive index which is less than a refractive index of the high refractive region.

According to an aspect of the disclosure, an image sensor includes: a pixel array including a center portion, a peripheral portion surrounding the center portion, and an end portion corresponding to an outer portion of the peripheral portion, the pixel array further including a plurality of pixels, wherein each of the plurality of pixels includes a light collector configured to collect light, wherein a light collector in the center portion includes a first pattern including a high refractive region including a first refractive index and a low refractive region including a second refractive index which is less than the first refractive index, wherein a light collector in the peripheral portion includes a second pattern including a high refractive region including a third refractive index and a low refractive region including a fourth refractive index which is less than the third refractive index, wherein a light collector in the end portion includes a third pattern including a high refractive region including a fifth refractive index and a low refractive region including a sixth refractive index which is less than the fifth refractive index, and wherein the first pattern, the second pattern, and the third pattern differ.

### BRIEF DESCRIPTION OF DRAWINGS

The above and other aspects and features of certain embodiments of the present disclosure will be more apparent from the following description taken in conjunction with the accompanying drawings, in which:

FIG. 1 is a block diagram illustrating a schematic configuration of an image sensor according to one or more embodiments;

FIG. 2 is a plan view illustrating an example of a pixel illustrated in FIG. 1;

FIG. 3A is a diagram illustrating an example of a cross-sectional configuration taken along line a-a illustrated in FIG. 2;

FIG. 3B is a diagram illustrating an example of a cross-sectional configuration taken along line b-b illustrated in FIG. 2;

FIG. 4A is a block diagram illustrating an example of a configuration of each of a red pixel, a green pixel, and a blue pixel each illustrated in FIG. 2;

FIG. 4B is a block diagram illustrating an example of a configuration of a detection pixel illustrated in FIG. 2;

FIG. 5A is a diagram illustrating an example of a plane configuration of a main part of an image sensor according to a comparative example;

FIG. 5B is a diagram illustrating an example of a cross-sectional configuration taken along line b-b illustrated in FIG. 5A;

FIG. 6A is a diagram to describe a light collection region of each pixel illustrated in FIG. 5A;

FIG. 6B is a cross-sectional view illustrating a light collection region of a green pixel illustrated in FIG. 6A;

FIG. 7A is a diagram to describe a light collection region of each pixel illustrated in FIG. 2;

FIG. 7B is a cross-sectional view illustrating a light collection region of a green pixel illustrated in FIG. 7A;

FIG. 8A is a diagram illustrating an example of a plane configuration of a main part of an image sensor according to one or more embodiments;

FIG. 8B is a diagram illustrating an example of a cross-sectional configuration taken along line b-b illustrated in FIG. 8A;

FIG. 9 is a diagram to describe a light collection region of each pixel illustrated in FIG. 8A;

FIG. 10 is a diagram to describe a wave surface of light incident on the image sensor illustrated in FIG. 2;

FIG. 11 is a diagram to describe a wave surface of light incident on the image sensor illustrated in FIG. 8A;

FIG. 12A is a diagram illustrating an example of a plane configuration of an image sensor according to one or more embodiments;

FIG. 12B is a diagram to describe an example of an arrangement of patterns of a high refractive region and a low refractive region each illustrated in FIG. 12A;

FIG. 13A is a diagram illustrating an example of a plane configuration of a red pixel of an image sensor according to one or more embodiments;

FIG. 13B is a diagram illustrating an example of a cross-sectional configuration taken along line b-b illustrated in FIG. 13A;

FIG. 14A is a diagram to describe an example of a red pixel having a pattern differing from patterns of a high refractive region and a low refractive region each illustrated in FIG. 13A;

FIG. 14B is a diagram illustrating an example of a cross-sectional configuration taken along line b-b illustrated in FIG. 14A;

FIG. 15A is a diagram to describe an example of a red pixel having a pattern differing from the patterns of the high refractive region and the low refractive region each illustrated in FIGS. 13A and 14A;

FIG. 15B is a diagram illustrating an example of a cross-sectional configuration taken along line b-b illustrated in FIG. 15A;

FIG. 16A is a diagram illustrating an example of a cross-sectional configuration of each of a green pixel and a blue pixel in an image sensor according to one or more embodiments;

FIG. 16B is a diagram illustrating an example of a cross-sectional configuration of a detection pixel in the image sensor illustrated in FIG. 16A;

FIG. 17A is a diagram illustrating an example of a plane configuration of a main part of an image sensor according to one or more embodiments;

FIG. 17B is a diagram illustrating an example of a cross-sectional configuration taken along line b-b illustrated in FIG. 17A;

FIG. 18 is a diagram illustrating another example of a plane configuration of a main part in the image sensor illustrated in FIG. 17A;

FIG. 19A is a diagram illustrating another example of a plane configuration of a main part in the image sensor illustrated in FIG. 17A;

FIG. 19B is a diagram illustrating an example of a cross-sectional configuration taken along line b-b illustrated in FIG. 19A;

FIG. 20A is a diagram illustrating another example of a plane configuration of a main part in the image sensor illustrated in FIG. 17A;

FIG. 20B is a diagram illustrating an example of a cross-sectional configuration taken along line b-b illustrated in FIG. 20A;

FIG. 21 is a diagram illustrating another example of a cross-sectional configuration of a main part of the image sensor illustrated in FIG. 20B;

FIG. 22A is a diagram illustrating another example of a plane configuration of a main part of the image sensor illustrated in FIG. 17A;

FIG. 22B is a diagram illustrating an example of a cross-sectional configuration taken along line b-b illustrated in FIG. 22A;

FIG. 23A is a diagram illustrating another example of a plane configuration of a main part of the image sensor illustrated in FIG. 17A;

FIG. 23B is a diagram illustrating an example of a cross-sectional configuration taken along line b-b illustrated in FIG. 23A;

FIG. 24 is a diagram illustrating an example of a cross-sectional configuration of a main part of an image sensor according to one or more embodiments;

FIG. 25 is a diagram illustrating another example of a cross-sectional configuration of a main part of the image sensor illustrated in FIG. 24;

FIG. 26 is a diagram illustrating another example of a cross-sectional configuration of a main part of the image sensor illustrated in FIG. 24;

FIG. 27 is a diagram illustrating another example of a cross-sectional configuration of a main part of the image sensor illustrated in FIG. 24;

FIG. 28 is a diagram illustrating another example of a cross-sectional configuration of a main part of the image sensor illustrated in FIG. 24;

FIG. 29A is a diagram illustrating an example of a plane configuration of a main part of an image sensor according to one or more embodiments;

FIG. 29B is a diagram illustrating an example of a cross-sectional configuration taken along line b-b illustrated in FIG. 29A;

FIG. 30 is a diagram illustrating another example of a plane configuration of a pixel illustrated in FIG. 2;

FIG. 31 is a diagram illustrating another example of a plane configuration of the pixel illustrated in FIG. 2;

FIG. 32 is a diagram illustrating another example of a plane configuration of the pixel illustrated in FIG. 2;

FIG. 33 is a diagram illustrating another example of a circuit configuration of a detection pixel illustrated in FIG. 4B; and

FIG. 34 is a diagram illustrating another example of a circuit configuration of the detection pixel illustrated in FIG. 4B.

### DETAILED DESCRIPTION

Hereinafter, one or more embodiments will be described in detail with reference to the accompanying drawings. In the drawings, like reference numeral refers to like element, and the elements illustrated in the drawings may not be drawn to scale, for clarity and convenience of description. The one or more embodiments described below are merely examples, and various modifications may be implemented on the disclosed embodiments.

Hereinafter, being described as “on” or “over” may include not being in contact as well as contacting and being just on.

A singular form of elements may include a plural form unless another case is clearly designated in context. Also, when an arbitrary portion includes or has an arbitrary element, this may denote further including another element instead of excluding another element, unless oppositely described.

Also, the use of the term “the” and the term similar thereto may correspond to all of the singular number and the plural number.

An order may be clearly described on operations configuring a method, or unless oppositely described, the operations may be performed in an appropriate order. The disclosure is not limited to the description order of the operations. The use of all examples or terms (for example, etc.) may be merely for describing the disclosure, and unless defined by claims, the spirit scope is not limited by the examples or the terms.

As used herein, a plurality of “units”, “modules”, “members”, and “blocks” may be implemented as a single component, or a single “unit”, “module”, “member”, and “block” may include a plurality of components.

It will be understood that when an element is referred to as being “connected” with or to another element, it can be directly or indirectly connected to the other element.

Also, when a part “includes” or “comprises” an element, unless there is a particular description contrary thereto, the part may further include other elements, not excluding the other elements.

As used herein, the expressions “at least one of a, b or c” and “at least one of a, b and c” indicate “only a,” “only b,” “only c,” “both a and b,” “both a and c,” “both b and c,” and “all of a, b, and c.”

It will be understood that, although the terms “first”, “second”, “third”, etc., may be used herein to describe various elements, is the disclosure should not be limited by these terms. These terms are only used to distinguish one element from another element.

As used herein, the singular forms “a,” “an” and “the” are intended to include the plural forms as well, unless the context clearly indicates otherwise.

With regard to any method or process described herein, an identification code may be used for the convenience of the description but is not intended to illustrate the order of each step or operation. Each step or operation may be implemented in an order different from the illustrated order unless the context clearly indicates otherwise. One or more steps or operations may be omitted unless the context of the disclosure clearly indicates otherwise.

The various actions, acts, blocks, steps, or the like in the flow diagrams may be performed in the order presented, in a different order, or simultaneously. Further, in one or more embodiments, some of the actions, acts, blocks, steps, or the like may be omitted, added, modified, skipped, or the like without departing from the scope of the disclosure.

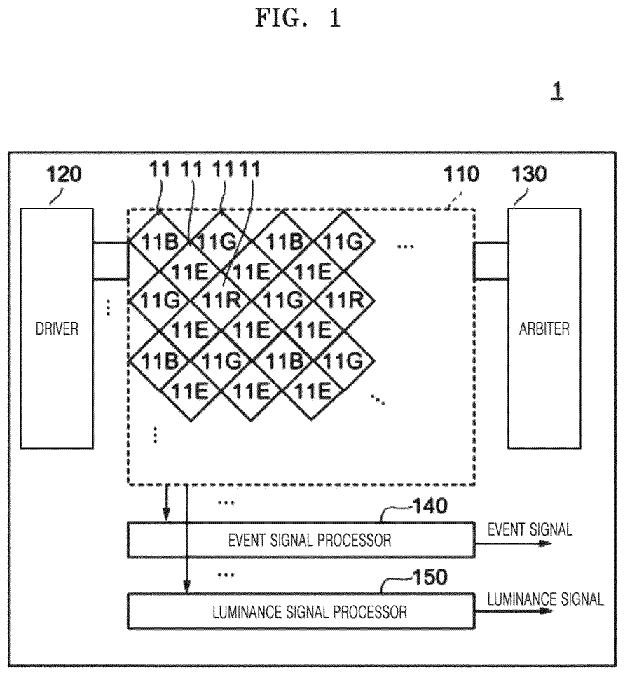

FIG. 1 is a block diagram illustrating a schematic configuration of an image sensor 1 according to one or more embodiments. Referring to FIG. 1, the image sensor 1 may include a pixel array 110, a driver 120, an arbiter 130, an event signal processor 140, and a luminance signal processor 150.

The pixel array 110 may include, for example, a tetragonal planar shape. The pixel array 110 may include, for example, a plurality of pixels 11, which are regularly arranged. The pixel 11 may include a red pixel 11R, a green pixel 11G, a blue pixel 11B, and a detection pixel 11E, and a unit pixel group may be repeatedly arranged in the pixel array 110. According to one or more embodiments, the red pixel 11R, the green pixel 11G, and the blue pixel 11B may respectively correspond to an embodiment of a first grayscale pixel, a second grayscale pixel, and a third grayscale pixel of the disclosure. The detection pixel 11E may sense a variation of the amount of received light over time. According to one or more embodiments, the detection pixel 11E may be a dynamic vision sensor (DVS).

In the image sensor 1, the red pixel 11R, the green pixel 11G, and the blue pixel 11B may be disposed adjacent to the detection pixel 11E. In the image sensor 1 according to one or more embodiments, a grayscale pixel and a detection pixel may be disposed in one semiconductor chip. The image sensor 1 may be applied to an application responding to motion blur.

The driver 120 may provide a control signal to each of the red pixel 11R, the green pixel 11G, and the blue pixel 11B. Therefore, the red pixel 11R, the green pixel 11G, and the blue pixel 11B may be driven.

The arbiter 130 may adjust a request of an event signal output from the detection pixel 11E. More specifically, when the arbiter 130 receives a request of an event signal output from the detection pixel 11E, the arbiter 130 may transfer an allowance or disallowance signal to the detection pixel 11E. The detection pixel 11E, which has received the allowance signal from the arbiter 130, may or may not output an event signal to the event signal processor 140 based on the allowance or disallowance signal from the arbiter 130. The event signal will be described below.

The event signal processor 140 may perform processing on an event signal output from the detection pixel 11E. The event signal on which processing has been performed by the event signal processor 140 may be transferred to a data processor.

The luminance signal processor 150 may include, for example, an analog-to-digital converter (ADC). The luminance signal processor 150 may perform analog-to-digital (AD) conversion on an analog luminance signal generated by each of the red pixel 11R, the green pixel 11G, and the blue pixel 11B to transfer to the data processor.

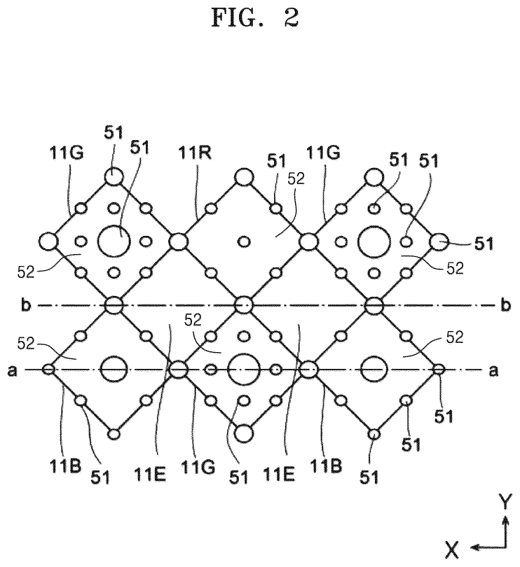

FIG. 2 illustrates an embodiment of a plane configuration of each pixel 11.

In the pixel array 110, for example, each of the red pixel 11R, the green pixel 11G, the blue pixel 11B, and the detection pixel 11E may be arranged at a certain pitch interval. For example, the unit pixel group may include one red pixel 11R, two green pixels 11G, one blue pixel 11B, and four detection pixels 11E. For example, the total number of red pixels 11R, green pixels 11G, and blue pixels 11B included in the unit pixel group may be equal to the total number of detection pixels 11E included in the unit pixel group. Each of the red pixel 11R, the green pixel 11G, the blue pixel 11B, and the detection pixel 11E may include, for example, a tetragonal planar shape. Each of the red pixel 11R, the green pixel 11G, the blue pixel 11B, and the detection pixel 11E may include, for example, the same planar shape. An area of a light-receiving surface of each of the red pixel 11R, the green pixel 11G, and the blue pixel 11B may be greater than or equal to that of a light-receiving surface of the detection pixel 11E. For example, a size of each of the red pixel 11R, the green pixel 11G, and the blue pixel 11B may be greater than or equal to that of the detection pixel 11E.

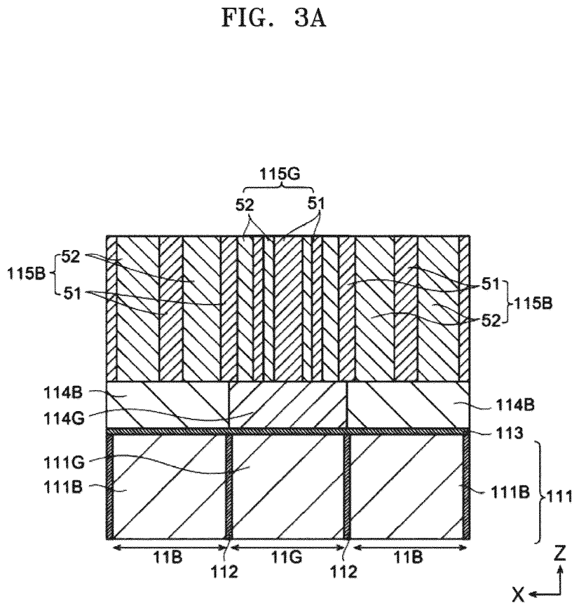

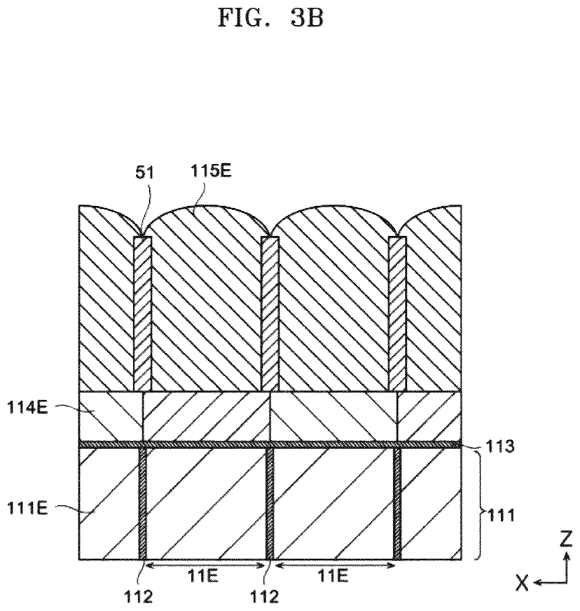

FIG. 3A is a diagram illustrating an example of a cross-sectional configuration taken along line a-a illustrated in FIG. 2, and FIG. 3B is a diagram illustrating an example of a cross-sectional configuration taken along line b-b illustrated in FIG. 2. Referring to FIG. 3A, a green photoelectric converter 111G, an antireflection layer 113, a green color filter 114G, and a green light collector 115G may be sequentially stacked and formed in the green pixel 11G. Referring to FIG. 3A, a blue photoelectric converter 111B, the antireflection layer 113, a blue color filter 114B, and a blue light collector 115B may be sequentially stacked and formed in the blue pixel 11B. According to one or more embodiments, a red photoelectric converter 111R, the antireflection layer 113, a red color filter 114R, and a red light collector 115R may be sequentially stacked and formed in the red pixel 11R. Referring to FIG. 3B, a detection photoelectric converter 111E, the antireflection layer 113, a detection color filter 114E, and a detection light collector 115E may be sequentially stacked and formed in the detection pixel 11E. A device isolation unit 112 may be disposed around each of the red photoelectric converter 111R, the green photoelectric converter 111G, the blue photoelectric converter 111B, and the detection photoelectric converter 111E.

Referring to FIGS. 3A and 3B, the red photoelectric converter 111R, the green photoelectric converter 111G, the blue photoelectric converter 111B, and the detection photoelectric converter 111E may be disposed in, for example, a semiconductor substrate 111. According to one or more embodiments, the red photoelectric converter 111R, the green photoelectric converter 111G, the blue photoelectric converter 111B, and the detection photoelectric converter 111E may each include a photodiode. Each of the red photoelectric converter 111R, the green photoelectric converter 111G, the blue photoelectric converter 111B, and the detection photoelectric converter 111E may generate an electric charge based on the amount of received light and may accumulate the generated electric charge up to a certain amount.

In the following description, a stack direction of a photoelectric converter (for example, the green photoelectric converter 111G), the antireflection layer 113, a color filter (for example, the green color filter 114G), and a light collector (for example, the green light collector 115G) may be referred to as a Z direction, a direction perpendicular to the Z direction may be referred to as an X direction, and a direction perpendicular to the Z direction and the X direction may be referred to as a Y direction.

Referring to FIGS. 3A and 3B, the device isolation unit 112 may electrically isolate the red pixel 11R, the green pixel 11G, the blue pixel 11B, and the detection pixel 11E from one another. The device isolation unit 112 may include, for example, polycrystalline silicon (p-Si). The device isolation unit 112 may be formed up to a backside of the semiconductor substrate 111 from a surface of the semiconductor substrate 111.

The antireflection layer 113 disposed on the semiconductor substrate 111 may prevent light from being reflected by the surface of the semiconductor substrate 111. The antireflection layer 113 may include, for example, oxide silicon (SiOx), nitride silicon (SiNx), oxynitride silicon (SiOxNy), oxide hafnium (HfO), or oxide tantalum (TaO). A fixed charge layer may be disposed between the antireflection layer 113 and the semiconductor substrate 111.

The red color filter 114R may selectively transmit light of a red wavelength range. The green color filter 114G may selectively transmit light of a green wavelength range. The blue color filter 114B may selectively transmit light of a blue wavelength range. The red color filter 114R, the green color filter 114G, and the blue color filter 114B may be provided, thereby preventing color mixture between pixels. The detection color filter 114E may selectively transmit, for example, light of a red wavelength range, a green wavelength range, or a blue wavelength range. The detection color filter 114E may be a transparent layer.

Each of the red light collector 115R, the green light collector 115G, and the blue light collector 115B may collect light of a wavelength of a visible light range. The red light collector 115R may allow light of a red wavelength range of incident light to be collected in the red photoelectric converter 111R. The green light collector 115G may allow light of a green wavelength range of incident light to be collected in the green photoelectric converter 111G. The blue light collector 115B may allow light of a blue wavelength range of incident light to be collected in the blue photoelectric converter 111B.

In one or more embodiments, a high refractive region 51 and a low refractive region 52 having a refractive index which is lower than that of the high refractive region 51 may be disposed in the green light collector 115G with a certain pattern. Although described below in detail, therefore, light of a green wavelength region which is incident on the green light collector 115G may be incident on the green photoelectric converter 111G, and light of a green wavelength region of at least a portion of light incident on an adjacent detection pixel 11E may be incident on the green photoelectric converter 111G. In other words, a pattern of each of the high refractive region 51 and the low refractive region 52 may be formed in the green light collector 115G so that light of a green wavelength range travels toward the green photoelectric converter 111G from the detection pixel 11E.

Furthermore, the high refractive region 51 and the low refractive region 52 may be disposed in the blue light collector 115B with a pattern which differs from that of the green light collector 115G. Therefore, light of a blue wavelength range incident on the blue light collector 115B may be incident on the blue photoelectric converter 111B, and moreover, light of a blue wavelength range of at least a portion of light incident on an adjacent detection pixel 11E may be incident on the blue photoelectric converter 111B. In other words, a pattern of each of the high refractive region 51 and the low refractive region 52 may be formed in the blue light collector 115B so that light of a blue wavelength range travels toward the blue photoelectric converter 111B from the detection pixel 11E.

Furthermore, the high refractive region 51 and the low refractive region 52 may be disposed in the red light collector 115R with a pattern which differs from that of each of the green light collector 115G and the blue light collector 115B. Therefore, light of a red wavelength range incident on the red light collector 115R may be incident on the red photoelectric converter 111R, and moreover, light of a red wavelength range of at least a portion of light incident on an adjacent detection pixel 11E may be incident on the red photoelectric converter 111R. In other words, a pattern of each of the high refractive region 51 and the low refractive region 52 may be formed in the red light collector 115R so that light of a red wavelength range travels toward the red photoelectric converter 111R from the detection pixel 11E.

The high refractive region 51 may be a region having a certain refractive index. For example, a pillar-shaped structure extending in a Z direction may be disposed in the high refractive region 51. The structure may have, for example, a circular pillar shape or an angular pillar shape. For example, a refractive index of the high refractive region 51 may be adjusted by adjusting a refractive index of a material included in the structure disposed in the high refractive region 51. The structure may include, for example, at least one of crystalline silicon (c-Si), p-Si, amorphous silicon (a-Si), III-V compound semiconductor (for example, GaP, GaN, GaAs, etc.), carbide silicon (SiC), oxide titanium (TiO₂), and SiN.

A diameter (a size in an X direction and a Y direction) of the structure may be, for example, about 50 nm to about 500 nm. A height (a size in the Z direction) of the structure may be, for example, about 500 nm to about 2,000 nm.

A plurality of structures may be disposed in each of the red light collector 115R, the green light collector 115G, and the blue light collector 115B. For example, at least one of a dimension of a diameter of structure, an arrangement number of structure, an arrangement position of structure, and an arrangement interval of structure may differ in each of the red light collector 115R, the green light collector 115G, and the blue light collector 115B. Accordingly, the patterns of the high refractive region 51 and the low refractive region 52 may differ between the red light collector 115R, the green light collector 115G, and the blue light collector 115B. According to one or more embodiments, a plurality of structures having different dimensions of diameters may be disposed in each of the red light collector 115R, the green light collector 115G, and the blue light collector 115B.

The low refractive region 52 may be disposed between high refractive regions 51 apart from each other, in the red light collector 115R, the green light collector 115G, and the blue light collector 115B. The low refractive region 52 may include, for example, a dielectric material filled between the plurality of structures. The low refractive region 52 may include, for example, oxide silicon (SiO₂). According to one or more embodiments, the low refractive region 52 may include air.

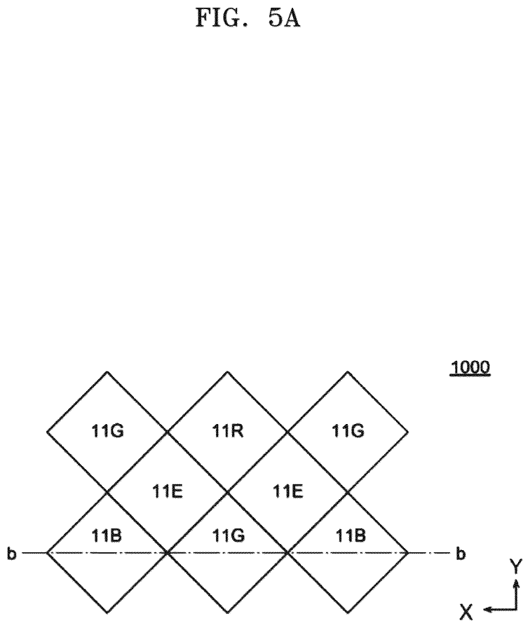

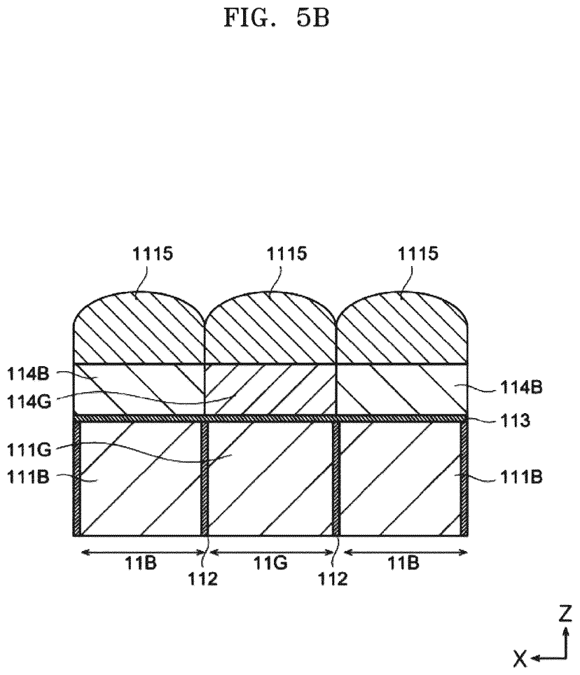

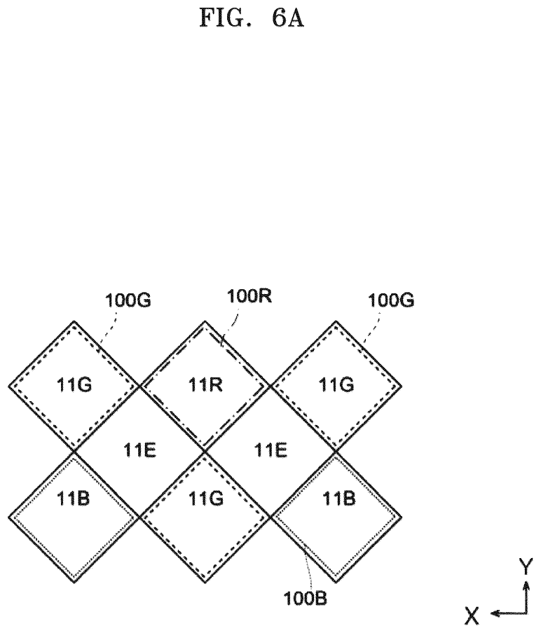

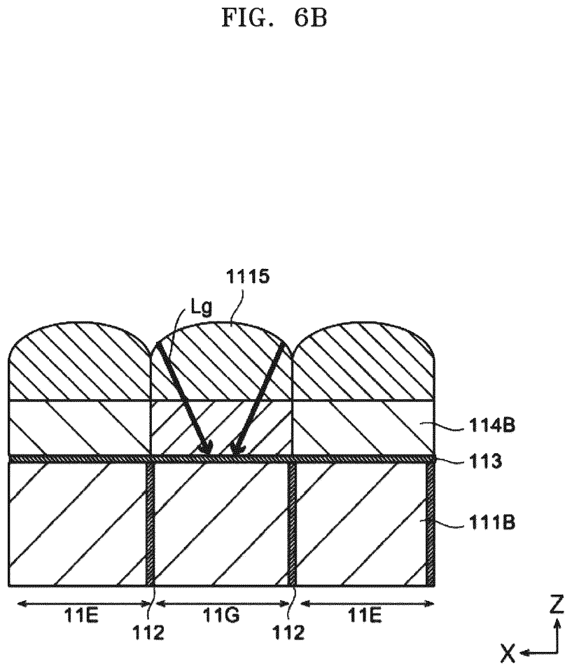

The detection light collector 115E may allow incident light to be collected in the detection photoelectric converter 111E. The detection light collector 115E may include, for example, an on-chip lens. The on-chip lens may include, for example, an inorganic material such as SiOx and SiNx. In the image sensor 1, the high refractive region 51 and the low refractive region 52 may be disposed in the green light collector 115G with a certain pattern. Therefore, light of a green wavelength range incident on the green light collector 115G may be incident on the green photoelectric converter 111G, and moreover, light of a green wavelength range of at least a portion of light incident on an adjacent detection pixel 11E may be incident on the green photoelectric converter 111G. This may be identically applied to the red light collector 115R and the blue light collector 115B. Therefore, the red pixel 11R, the green pixel 11G, and the blue pixel 11B may respectively receive light of a red wavelength range, light of a green wavelength range, and light of a blue wavelength range from an adjacent detection pixel 11E. Accordingly, a reduction in the amount of received light in the red pixel 11R, the green pixel 11G, and the blue pixel 11B may be prevented, or at least mitigated. Hereinafter, an effect of the disclosure will be described with reference to a comparative example and FIGS. 5A to 6B.

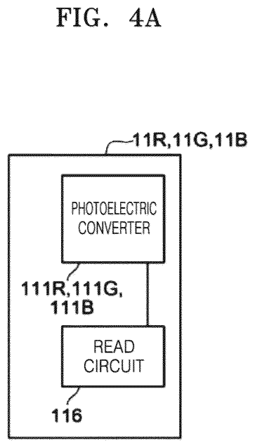

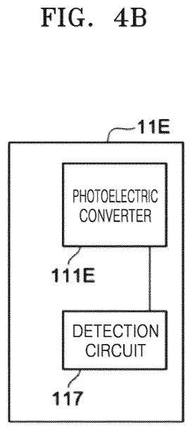

FIG. 4A is a block diagram illustrating an example of a configuration of each of the red pixel 11R, the green pixel 11G, and the blue pixel 11B each illustrated in FIG. 2, and FIG. 4B is a block diagram illustrating an example of a configuration of the detection pixel 11E illustrated in FIG. 2.

Referring to FIG. 4A, each of the red photoelectric converter 111R, the green photoelectric converter 111G, and the blue photoelectric converter 111B may be electrically connected to a read circuit 116. Referring to FIG. 4B, the detection photoelectric converter 111E may be electrically connected to a detection circuit 117.

Referring to FIG. 4A, a luminance signal obtained through photoelectric conversion by each of the red photoelectric converter 111R, the green photoelectric converter 111G, and the blue photoelectric converter 111B may be transferred to the read circuit 116. The read circuit 116 may read the transferred luminance signal to supply to the luminance signal processor 150, based on control by the driver 120.

Referring to FIG. 4B, an electrical signal obtained through photoelectric conversion by the detection photoelectric converter 111E may be transferred to the detection circuit 117. The detection circuit 117 may detect a time variation of the amount of light incident on the detection photoelectric converter 111E. In detail, when a variation, which is greater than a threshold value, occurs in the electrical signal obtained through photoelectric conversion by the detection photoelectric converter 111E, a variation of the electrical signal may be detected as an event. When the event is detected, the detection circuit 117 may output a request to output an event signal to the arbiter 130. When an allowance signal of the event signal output is received from the arbiter 130, the detection circuit 117 may supply an event signal to the event signal processor 140.

FIG. 5A is a diagram illustrating an example of a plane configuration of a main part of an image sensor 1000 according to a comparative example, and FIG. 5B is a diagram illustrating an example of a cross-sectional configuration taken along line b-b illustrated in FIG. 5A. Each of a red pixel 11R, a green pixel 11G, and a blue pixel 11B of the image sensor 1000 may include a light collector 1115. A high refractive region and a low refractive region (for example, the high refractive region and the low refractive region of FIG. 2) may not be disposed in the light collector 1115. The light collector 1115 may include, for example, an on-chip lens. In this context, the image sensor 1000 of FIG. 5A may include a configuration which differs from that of the image sensor 1 of FIG. 1.

FIGS. 6A and 6B schematically illustrate a light collection region 100R of the red pixel 11R, a light collection region 100G of the green pixel 11G, and a light collection region 100B of the blue pixel 11B. In the image sensor 1000, light Lg of a green wavelength range may be received by the green photoelectric converter 111G through only the green light collector 1115. In the image sensor 1000, due to the detection light collector 115E, it may be difficult to secure a sufficient size of the light collection region 100G. This may be identically applied to the other light collection regions 100G and 100B. Therefore, in the image sensor 1000, because a sufficient amount of received light in the red pixel 11R, the green pixel 11G, and the blue pixel 11B is not maintained, sensitivity may be reduced. Also, such a sensor may be unable to generate an image in which luminance information and color information are sufficiently reflected.

On the other hand, in the image sensor 1 according to one or more embodiments, the high refractive region 51 and the low refractive region 52 may be disposed in each of the red light collector 115R, the green light collector 115G, and the blue light collector 115B with a certain pattern. Therefore, the light collection region of each of the red pixel 11R, the green pixel 11G, and the blue pixel 11B may enlarge.

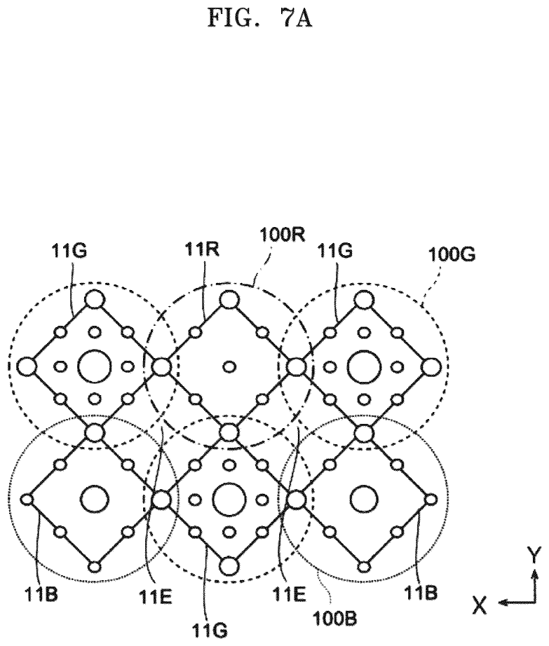

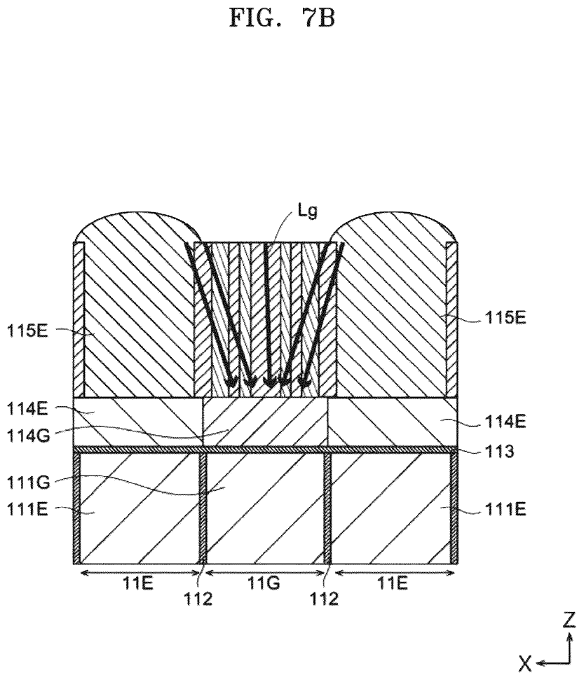

FIGS. 7A and 7B schematically illustrate the light collection regions 100R, 100G, and 100B in the image sensor 1. In the image sensor 1 according to one or more embodiments, the high refractive region 51 and the low refractive region 52 may be disposed in the green light collector 115G with a certain pattern, and thus, light of a green wavelength range of at least a portion of light incident on the detection light collector 115E may travel toward to the green light collector 115G. Furthermore, light of a green wavelength range of at least a portion of light incident on adjacent blue light collector 115B and red light collector 115R may travel toward to the green light collector 115G. As described above, because the light collection region 100G is formed across a range which is wider than the green light collector 115G, it may be easier to maintain the sufficient amount of received light.

Also, the high refractive region 51 and the low refractive region 52 may be disposed in the blue light collector 115B with a pattern which differs from that of the green light collector 115G. Furthermore, the high refractive region 51 and the low refractive region 52 may be disposed in the red light collector 115R with a pattern which differs from that of each of the green light collector 115G and the blue light collector 115B. Therefore, as described above, because the light collection regions 100B and 100R are formed to have a range which is wider than the blue light collector 115B and the red light collector 115R, it may be easier to maintain the sufficient amount of received light. Accordingly, in the image sensor 1, because the sufficient amount of received light in the red pixel 11R, the green pixel 11G, and the blue pixel 11B is maintained, a reduction in sensitivity may be prevented. Also, the image sensor 1 may generate an image in which luminance information and color information are sufficiently reflected.

Furthermore, in the image sensor 1, for example, the light collection regions 100R, 100G, and 100B may be formed to have almost the same size. Accordingly, an image where resolution is high and balance is good may be generated.

Hereinafter, another embodiment of the image sensor 1 described above will be described. In the following description, in order to avoid repeated descriptions, a detailed description of the same element as each element of the image sensor 1 described above is omitted.

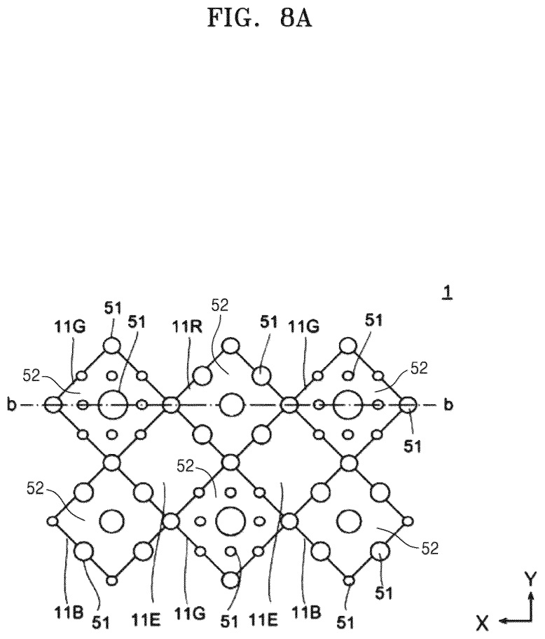

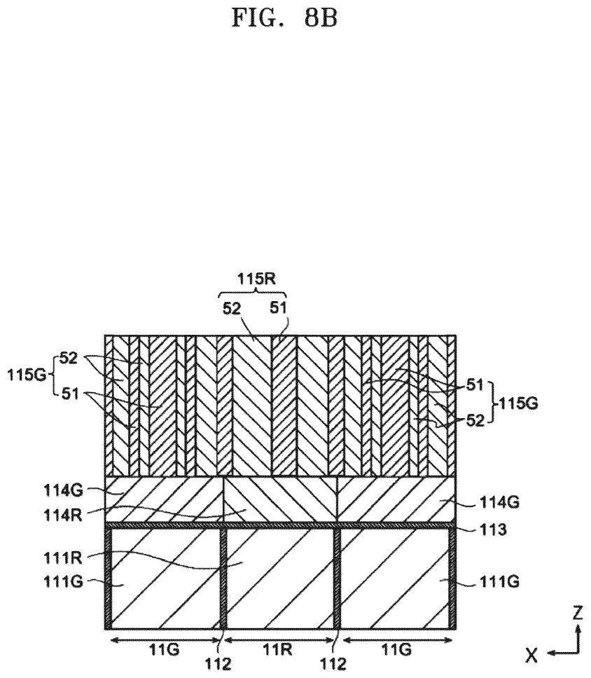

FIGS. 8A and 8B illustrate an example of a configuration of a main part of an image sensor 1 according to one or more embodiments. FIG. 8A illustrates an example of a plane configuration of each pixel 11. FIG. 8B illustrates an example of a cross-sectional configuration taken along line b-b illustrated in FIG. 8A. The image sensor 1 of FIG. 8A may have a pattern which differs from that of each of the high refractive region 51 and the low refractive region 52 each illustrated in FIG. 2. In this context, the image sensor 1 of FIGS. 8A and 8B may differ from the image sensor 1 of FIG. 2.

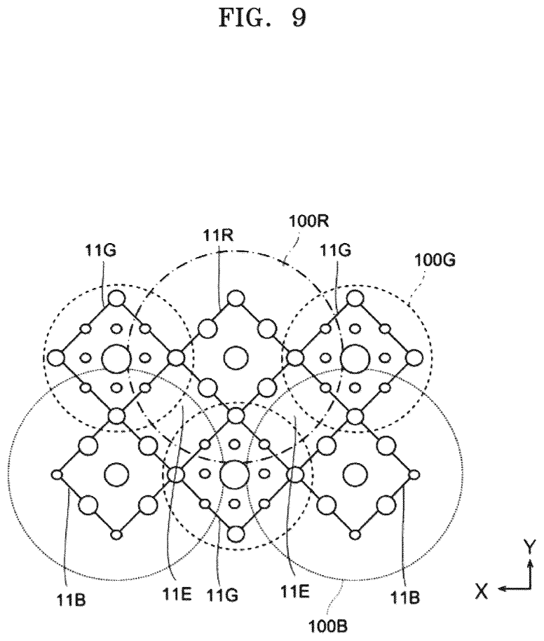

FIG. 9 schematically illustrates light collection regions 100R, 100G, and 100B in the image sensor 1. In the image sensor 1 of FIG. 9, the light collection regions 100R and 100B may be larger than the light collection region 100G. As described above, sizes of the light collection regions 100R, 100G, and 100B may be differently changed based on a wavelength range of collected light.

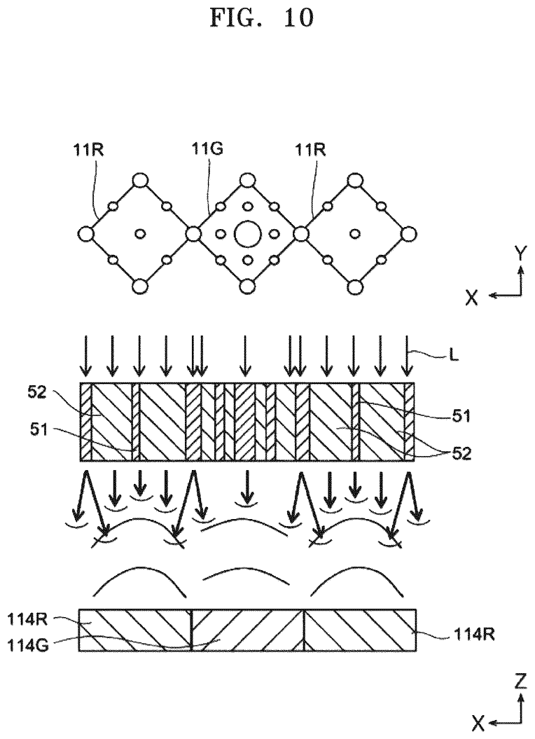

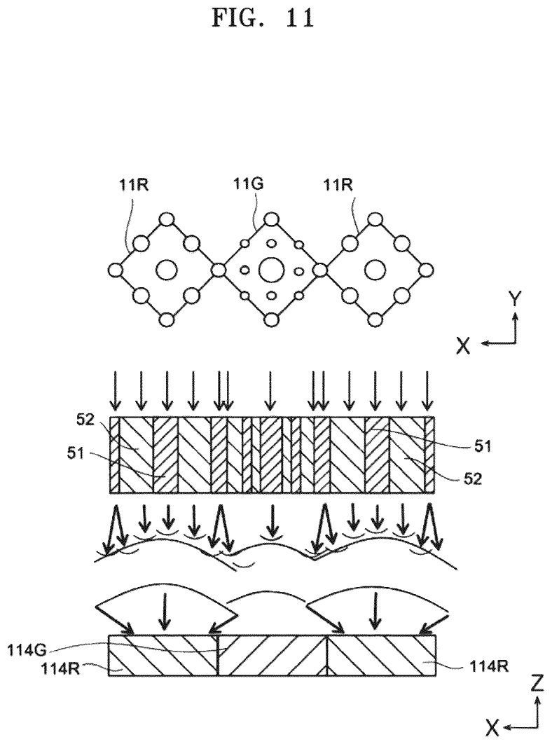

FIGS. 10 and 11 are schematic diagrams illustrating a relationship between a wave surface and a size of a high refractive region 51. A size of the high refractive region 51, for example, may be proportional to a diameter of a structure configuring the high refractive region 51. In FIG. 10, a pattern of each of the high refractive region 51 and a low refractive region 52, each illustrated in FIG. 2, is illustrated. In FIG. 11, a pattern of each of the high refractive region 51 and the low refractive region 52, each illustrated in FIG. 8A, is illustrated.

As a refractive index increases, a velocity of light may be reduced. In FIG. 8A (and FIG. 11), comparing with FIG. 2 (and FIG. 10), the high refractive region 51 of a portion of each of a red light collector 115R and a blue light collector 115B may be large, and moreover, the high refractive region 51 may be gently reduced toward a peripheral portion of a pixel as compared to a center portion of the pixel. Therefore, in a red pixel 11R and a blue pixel 11B, a velocity of light may be reduced, and thus, a wave surface of light may be more gently formed. Accordingly, the light collection regions 100R and 100B may be enlarged.

As described above, comparing with FIG. 2, the light collection regions 100R and 100B, which are wide, may be formed in the image sensor 1 having a pattern of each of the high refractive region 51 and the low refractive region 52, each illustrated in FIGS. 8A and 8B. Accordingly, a sensitivity of the image sensor 1 may be enhanced.

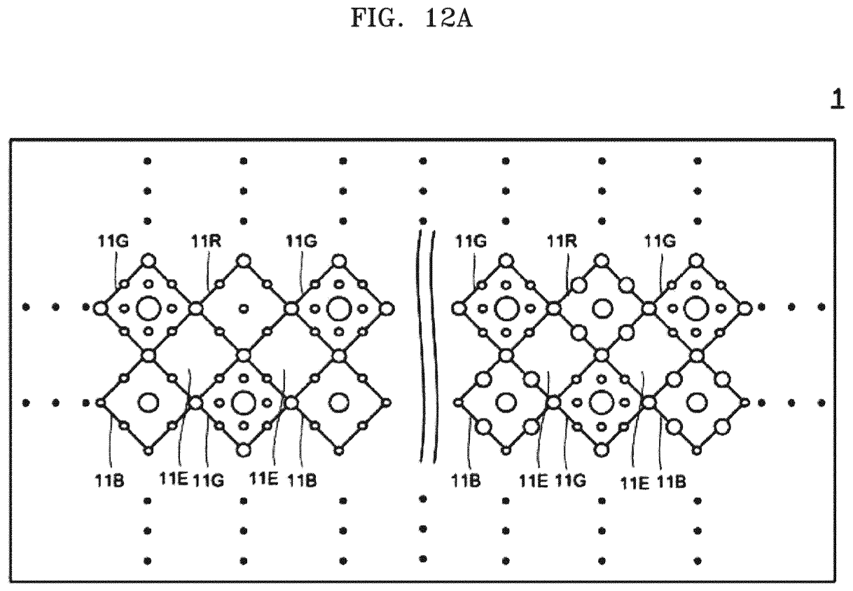

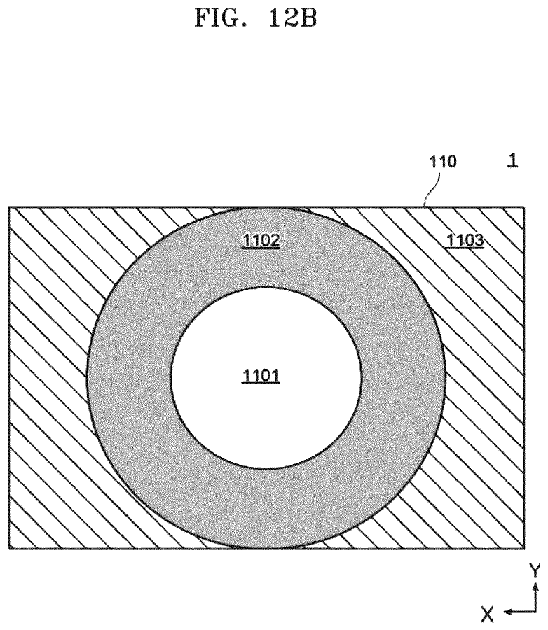

FIG. 12A is a diagram illustrating an example of a plane configuration of an image sensor 1 according to another embodiment. In the image sensor 1 of FIG. 12A, a pattern of each of the high refractive region 51 and the low refractive region 52, as illustrated in FIG. 2, and a pattern of each of the high refractive region 51 and the low refractive region 52, as illustrated in FIG. 8A, are illustrated. In this context, the image sensor 1 of FIG. 12A may differ from the image sensor 1 as described above.

In the image sensor 1, for example, a pattern of each of a high refractive region 51 and a low refractive region 52 may be differ based on positions of a red pixel 11R, a green pixel 11G, and a blue pixel 11B in a pixel array 110.

FIG. 12B illustrates an example of an arrangement of a structure pattern of the high refractive region 51 and the low refractive region 52. For example, a pattern of each of the high refractive region 51 and the low refractive region 52 may differ based on a position of each of a center portion 1101, a peripheral portion 1102, and an end portion 1103 of the pixel array 110. The center portion 1101 may be, for example, a circular portion disposed at a center of the pixel array 110 having a rectangular shape. The peripheral portion 1102 may be a ring-shaped portion surrounding the center portion 1101. The end portion 1103 may be an outer portion of the peripheral portion 1102.

For example, a red light collector 115R, a green light collector 115G, and a blue light collector 115B, where a structure pattern that emphasizes a resolution of the high refractive region 51 and the low refractive region 52, each illustrated in FIG. 2, may be disposed in the center portion 1101. A red light collector 115R, a green light collector 115G, and a blue light collector 115B in a pattern that emphasizes sensitivity of the high refractive region 51 and the low refractive region 52, as illustrated in FIG. 8A, may be disposed in the end portion 1103. By contrast, a red light collector 115R, a green light collector 115G, and a blue light collector 115B, disposed in a patter that gives balanced consideration to the sensitivity and the resolution of the high refractive region 51 and the low refractive region 52, as illustrated in FIGS. 2 and 8A, may be disposed in the peripheral portion 1102.

As described above, a pattern of each of the high refractive region 51 and the low refractive region 52 may differ based on positions of the red pixel 11R, the green pixel 11G, and the blue pixel 11B in the pixel array 110, and thus, both resolution and sensitivity may be optimized in the image sensor 1.

According to another embodiment, in the image sensor 1, each of the red light collector 115R, the green light collector 115G, and the blue light collector 115B may have a pattern other than one of the patterns illustrated in FIGS. 2 and 8A.

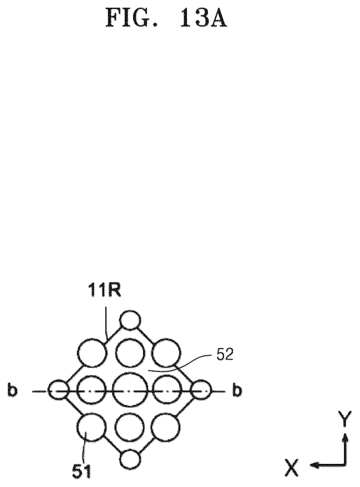

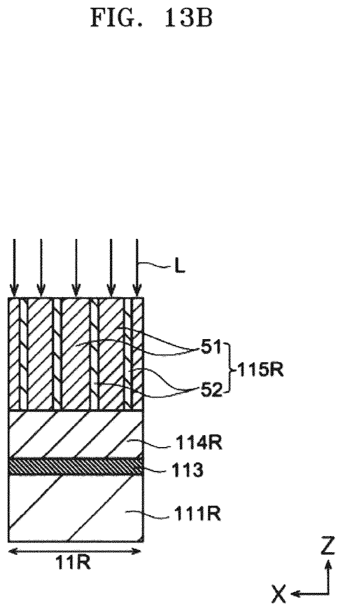

FIGS. 13A to 15B illustrate additional examples of a pattern of each of a high refractive region 51 and a low refractive region 52 disposed in a red light collector 115R. FIGS. 13A, 14A, and 15A illustrate a plane configuration of a red pixel 11R, and FIGS. 13B, 14B, and 15B illustrate a cross-sectional configuration taken along line b-b illustrated in FIGS. 13A, 14A, and 15A, respectively.

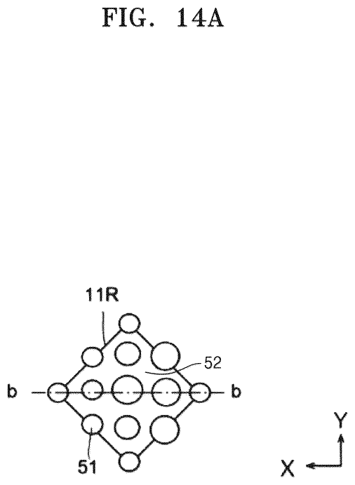

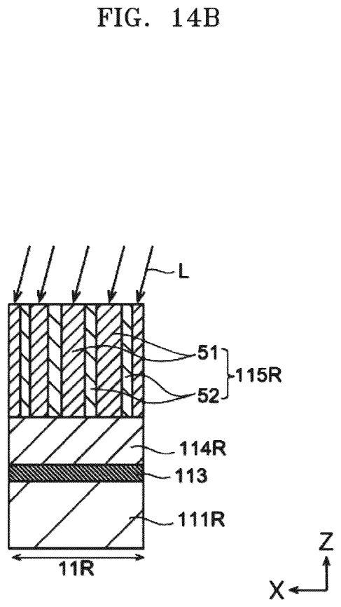

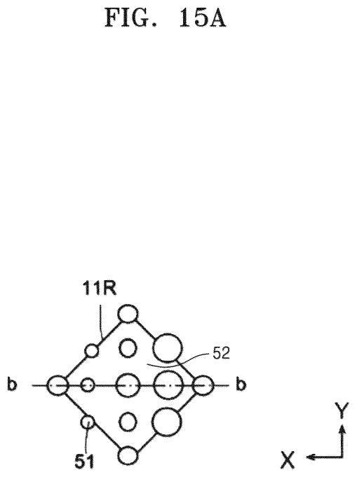

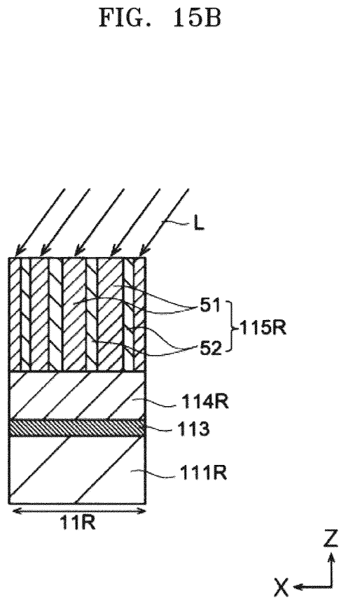

In a red pixel 11R illustrated in FIGS. 13A and 13B, a high refractive region 51 and a low refractive region 52 may be disposed to be highly symmetric with each other. In a red pixel 11R illustrated in FIGS. 14A and 14B, Y-axis symmetry may be collapsed compared to a pattern of each of the high refractive region 51 and the low refractive region 52 as illustrated in FIGS. 13A and 13B. In more detail, the red pixel 11R may be provided in a shape where the high refractive region 51 is reduced toward the left of the paper from the right of the paper. In a red pixel 11R illustrated in FIGS. 15A and 15B, Y-axis symmetry may be more collapsed compared to a pattern of each of the high refractive region 51 and the low refractive region 52 as illustrated in FIGS. 14A and 14B. In more detail, the high refractive region 51 may be more reduced at the left of the paper than the right of the paper.

For example, the red pixel 11R illustrated in FIGS. 13A and 13B may be disposed in the center portion 1101 of the pixel array 110. The red pixel 11R illustrated in FIGS. 14A and 14B may be disposed in the peripheral portion 1102 of the pixel array 110. The red pixel 11R illustrated in FIGS. 15A and 15B may be disposed in the end portion 1103 of the pixel array 110. Likewise, in a green pixel 11G and a blue pixel 11B, a pattern of each of the high refractive region 51 and a low refractive region 52 may differ based on the portion of the pixel array 110 the pixel is located.

As described above, a symmetry of the patterns of the high refractive region 51 and the low refractive region 52 may differ based on positions of the red pixel 11R, the green pixel 11G, and the blue pixel 11B in the pixel array 110. Therefore, light L, which is incident on the pixel array 110 at an angle in a Z direction at the peripheral portion 1102 and the end portion 1103, may be more efficiently transferred to the red photoelectric converter 111R, the green photoelectric converter 111G, and the blue photoelectric converter 111B.

As described above, the image sensor 1 according to one or more embodiments may include a red light collector 115R including a high refractive region 51 and a low refractive region 52 disposed with a first pattern and a red light collector 115R including a high refractive region 51 and a low refractive region 52 disposed with a second pattern which differs from the first pattern, and this may be identically applied to a green light collector 115G and a blue light collector 115B. In the image sensor 1, at least one of the red light collector 115R, the green light collector 115G, and the blue light collector 115B may include a high refractive region 51 and a low refractive region 52 disposed with the first pattern and the second pattern.

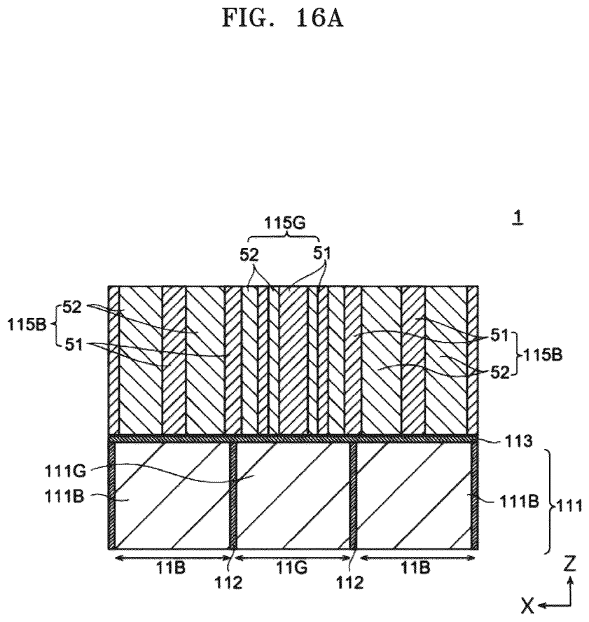

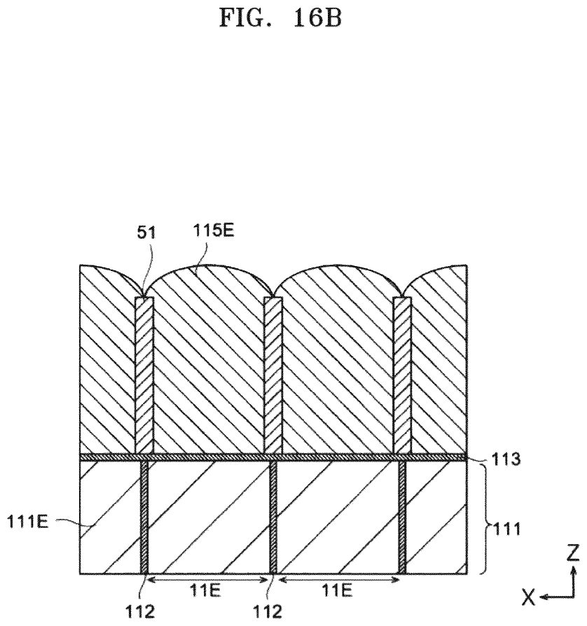

FIGS. 16A and 16B illustrate an example of a cross-sectional configuration of an image sensor 1 according to another embodiment. FIG. 16A may correspond to a cross-sectional configuration taken along line a-a illustrated in FIG. 2, and FIG. 16B may correspond to a cross-sectional configuration taken along line b-b illustrated in FIG. 2. A red color filter 114R, a green color filter 114G, a blue color filter 114B, and a detection color filter 114E may not be disposed in the image sensor 1 of FIGS. 16A and 16B. In this context, the image sensor 1 of FIGS. 16A and 16B may differ from the image sensor 1 as described above.

Referring to FIG. 16A, a green photoelectric converter 111G, an antireflection layer 113, and a green light collector 115G may be sequentially stacked in a green pixel 11G of the image sensor 1. Referring to FIG. 16A, a blue photoelectric converter 111B, the antireflection layer 113, and a blue light collector 115B may be sequentially stacked in a blue pixel 11B. A red photoelectric converter 111R, the antireflection layer 113, and a red light collector 115R may be sequentially stacked in a red pixel 11R. Referring to FIG. 16B, a detection photoelectric converter 111E, the antireflection layer 113, and a detection light collector 115E may be sequentially stacked in a detection pixel 11E.

In the image sensor 1, the red light collector 115R, the green light collector 115G, and the blue light collector 115B may perform a function of a color filter, and the color filters 114R, 114G, 114B, and 114E may not be included, thereby decreasing the manufacturing cost of the image sensor 1.

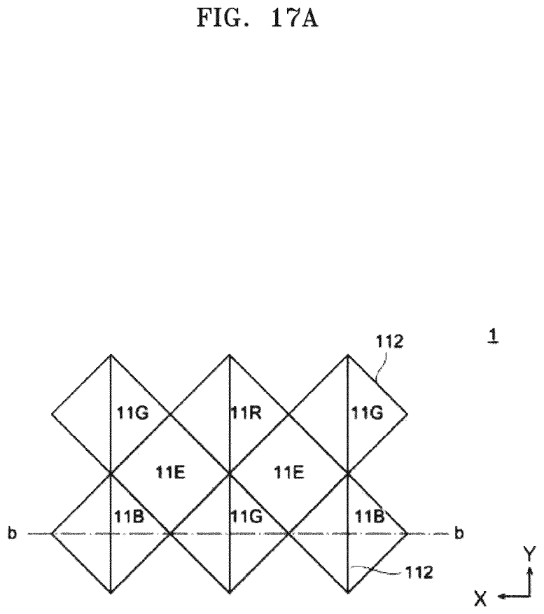

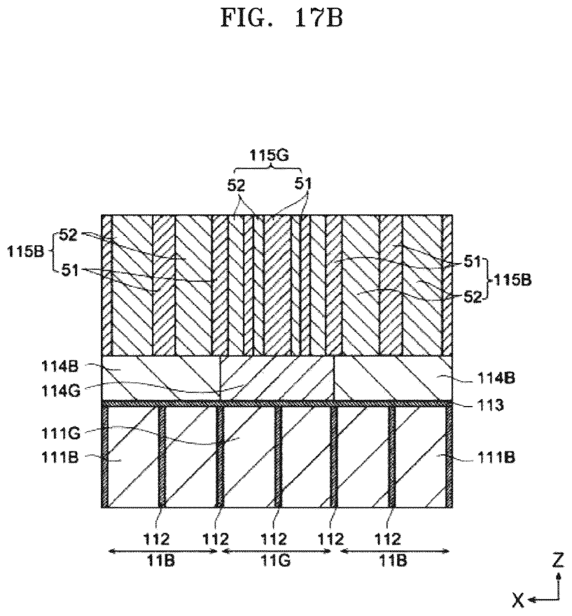

FIGS. 17A to 22B illustrate an example of a top view and a cross-sectional configuration of an image sensor 1 according to another embodiment. A phase detection auto focus (PDAF) pixel may be disposed in the image sensor 1 of FIGS. 17A to 22B. In this context, the image sensor 1 of FIGS. 17A to 22B may differ from the image sensor 1 described above.

FIG. 17A illustrates an example of a plane configuration of each pixel 11. FIG. 17B illustrates an example of a cross-sectional configuration taken along line b-b illustrated in FIG. 17A. A PDAF pixel, for example, may be disposed in a grayscale pixel, and in detail, may be disposed in a red pixel 11R, a green pixel 11G, and a blue pixel 11B. In the green pixel 11G of the PDAF pixel, for example, two green photoelectric converters 111G divided by a device isolation unit 112 including p-Si or SiO₂, may share a green light collector 115G. This may be identically applied to the blue pixel 11B and the red pixel 11R of the PDAF pixel.

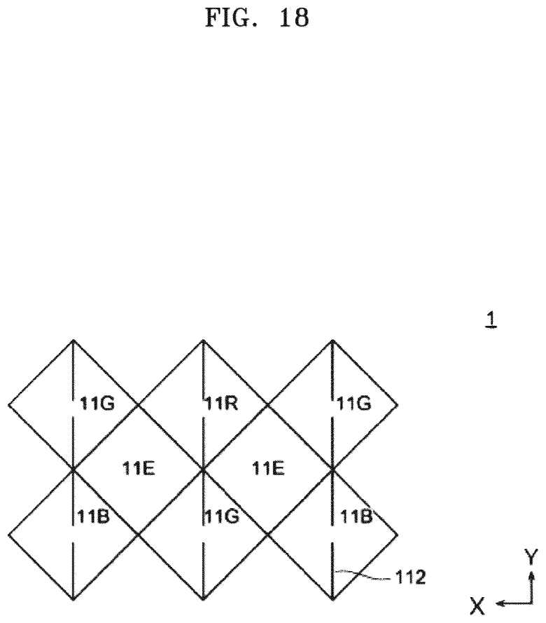

FIG. 18 illustrates another example of a plane configuration of each pixel 11 illustrated in FIG. 17A. In the green pixel 11G of the PDAF pixel, the two green photoelectric converters 111G may be connected to each other at a portion of the green pixel 11G (a portion where the device isolation unit 112 is not provided). This may be identically applied to the blue pixel 11B and the red pixel 11R of the PDAF pixel. In such a configuration, a red light collector 115R, a green light collector 115G, and a blue light collector 115B may be formed according to the embodiment described above.

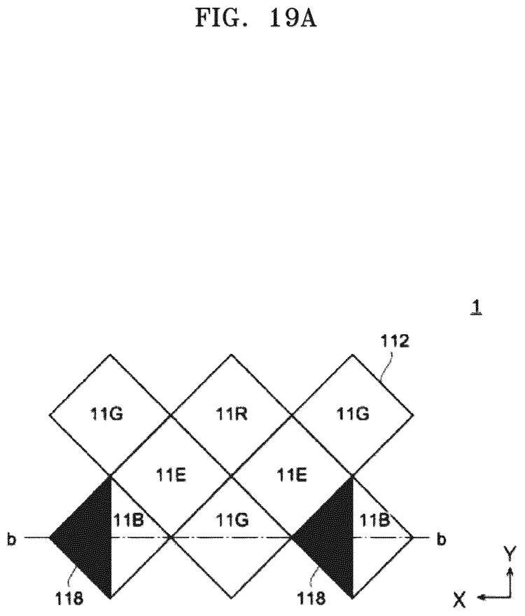

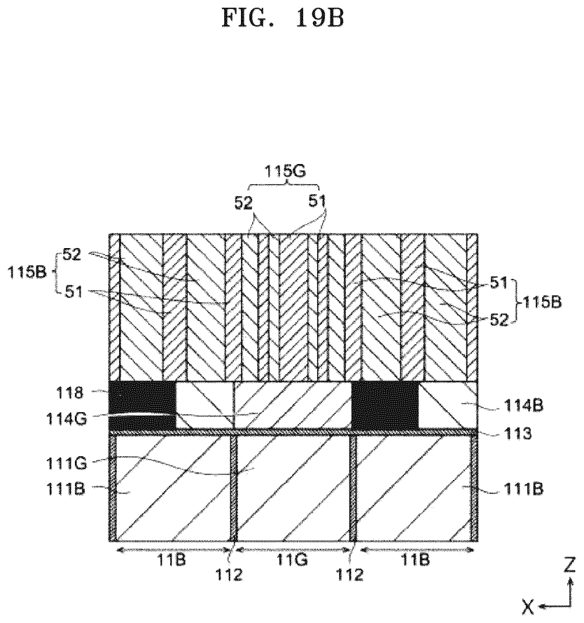

FIG. 19A illustrates another example of a plane configuration of each pixel 11 illustrated in FIG. 17A. FIG. 19B illustrates an example of a cross-sectional configuration taken along line b-b illustrated in FIG. 19A. In a green pixel 11G of a PDAF pixel, a portion of a green photoelectric converter 111G may be covered by a light blocking layer 118 (e.g., a metal layer including tungsten or TiN). This may be identically applied to the blue pixel 11B and the red pixel 11R of the PDAF pixel. In such a configuration, for example, a red light collector 115R, a green light collector 115G, and a blue light collector 115B may be formed on a color filter 114 and the light blocking layer 118 each formed to have the same thickness, according to the embodiment described above.

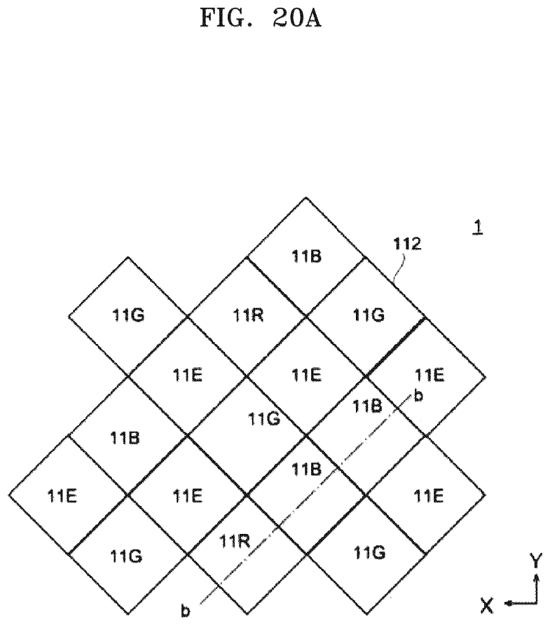

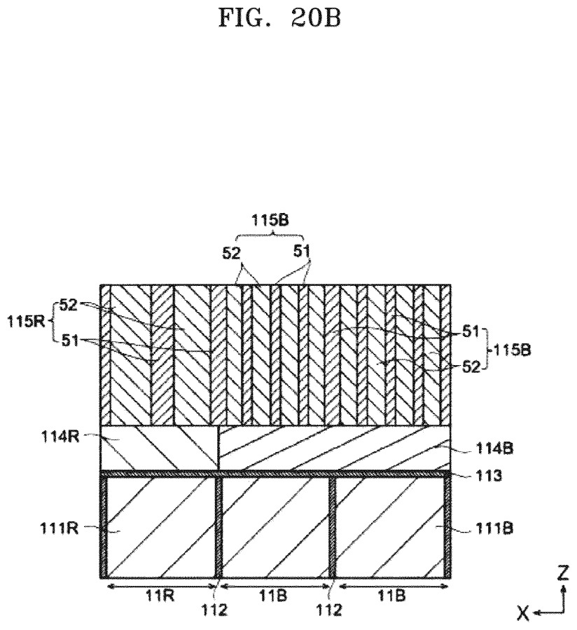

FIG. 20A illustrates another example of a plane configuration of each pixel 11 illustrated in FIG. 17A. FIG. 20B illustrates an example of a cross-sectional configuration taken along line b-b illustrated in FIG. 20A. For example, a PDAF pixel may be configured by two blue pixels 11B.

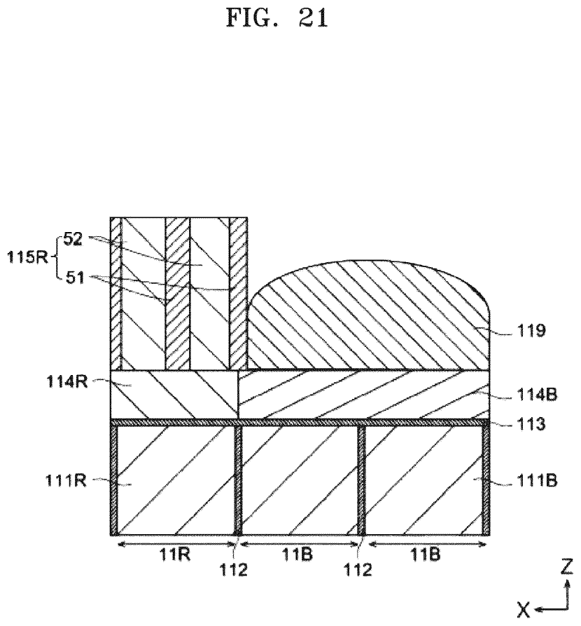

FIG. 21 illustrates another example of a cross-sectional configuration illustrated in FIG. 20B. An on-chip lens 119 may be shared by two blue pixels 11B configuring a PDAF pixel. The PDAF pixel may be disposed in a detection pixel 11E.

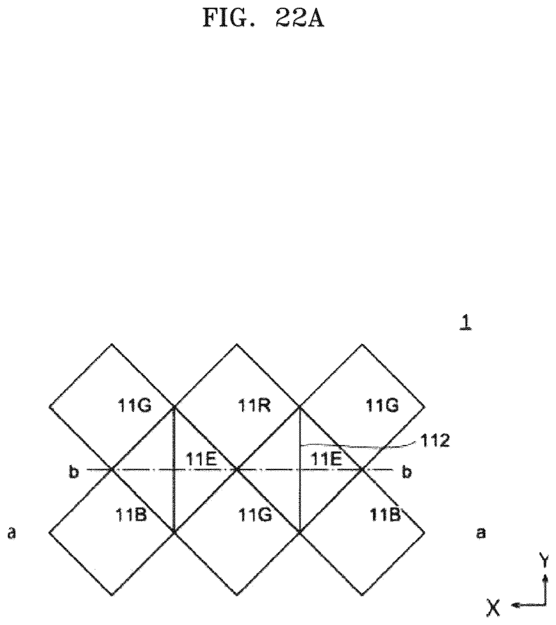

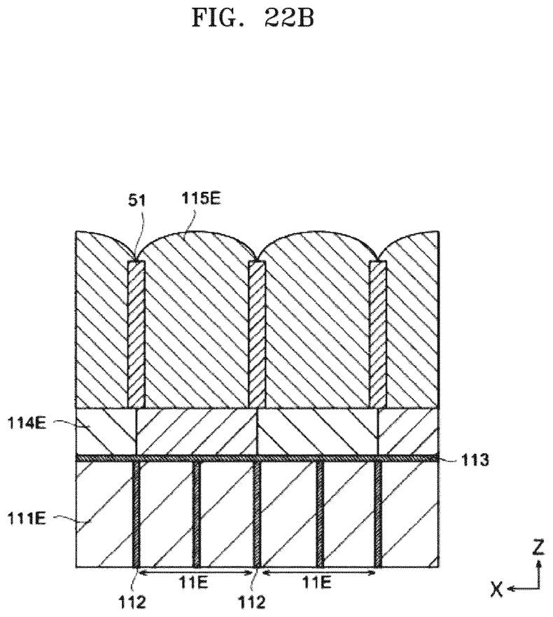

FIG. 22A illustrates an example of a plane configuration of each pixel 11. FIG. 22B illustrates an example of a cross-sectional configuration taken along line b-b illustrated in FIG. 22A. In a detection pixel 11E of a PDAF pixel, for example, two detection photoelectric converters 111E divided by a device isolation unit 112 may share a detection light collector 115E. Referring to another embodiment, as in FIG. 18, in the detection pixel 11E of the PDAF pixel, the two detection photoelectric converters 111E may be connected to each other at a portion of the detection pixel 11E (a portion where the device isolation unit 112 is not provided).

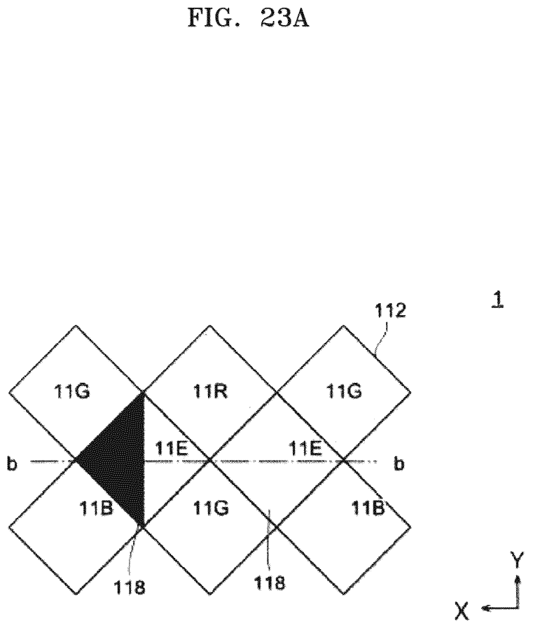

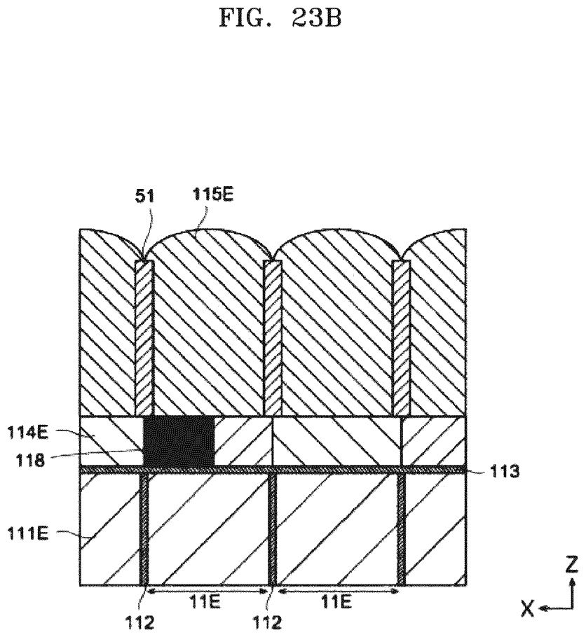

FIG. 23A illustrates another example of a plane configuration of each pixel 11 illustrated in FIG. 22A. FIG. 23B illustrates an example of a cross-sectional configuration taken along line b-b illustrated in FIG. 23A. In a detection pixel 11E of a PDAF pixel, for example, a portion of a detection photoelectric converter 111E may be covered by a light blocking layer 118.

As described above, in an image sensor 1 including the PDAF pixel, high-speed auto focus may be implemented.

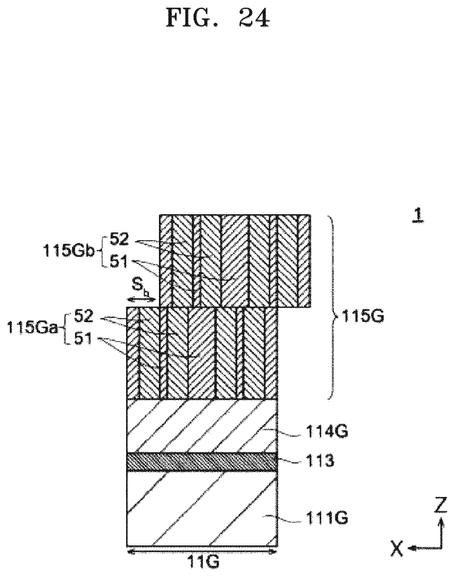

FIG. 24 illustrates an example of a cross-sectional configuration of a main part of an image sensor 1 according to another embodiment. A green pixel 11G of the image sensor 1 of FIG. 24 may include a green light collector 115G arranged in a stack structure. A red light collector 115R and a blue light collector 115B may also include a stack structure. In this context, the image sensor 1 of FIG. 24 may differ from the image sensor 1 as described above.

The green light collector 115G, for example, may include a first layer 115Ga and a second layer 115Gb stacked in a Z direction of the first layer 115Ga. A high refractive region 51 and a low refractive region 52 may be disposed in each of the first layer 115Ga and the second layer 115Gb with a certain pattern.

The second layer 115Gb, for example, may be disposed to be staggered by an amount of shift S_{b} from an end of the first layer 115Ga in an X direction. The second layer 115Gb may be disposed to be staggered by a certain amount of shift from an end of the first layer 115Ga in a Y direction. For example, an amount of shift S_{b} may differ between a plurality of green pixels 11G.

For example, in a green pixel 11G disposed in the end portion 1103 (FIG. 12) of the pixel array 110, an amount of shift S_{b} may increase compared to a green pixel 11G disposed in the center portion 1101 of the pixel array 110. As described above, an amount of shift S_{b} may be differently changed based on positions of the green pixels 11G of the pixel array 110. Therefore, light, which is incident on the pixel array 110 at an angle in a Z direction at the peripheral portion 1102 and the end portion 1103, may be more efficiently transferred to the green photoelectric converter 111G.

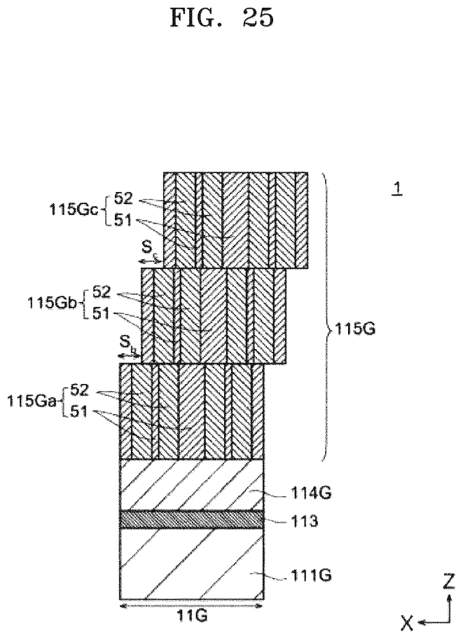

FIG. 25 illustrates another example of a cross-sectional configuration of the image sensor 1 illustrated in FIG. 24. A green light collector 115G of the image sensor 1 may further include a third layer 115Gc stacked in a Z direction of the second layer 115Gb. A high refractive region 51 and a low refractive region 52 may be disposed in the third layer 115Gc with a certain pattern.

The third layer 115Gc, for example, may be disposed to be staggered by an amount of shift S_{c} from an end of the second layer 115Gb in an X direction. The third layer 115Gc may be disposed to be staggered by a certain amount of shift from an end of the second layer 115Gb in a Y direction. An amount of shift (S_{b}, S_{c}) may be differently changed based on positions of the green pixels 11G of the pixel array 110.

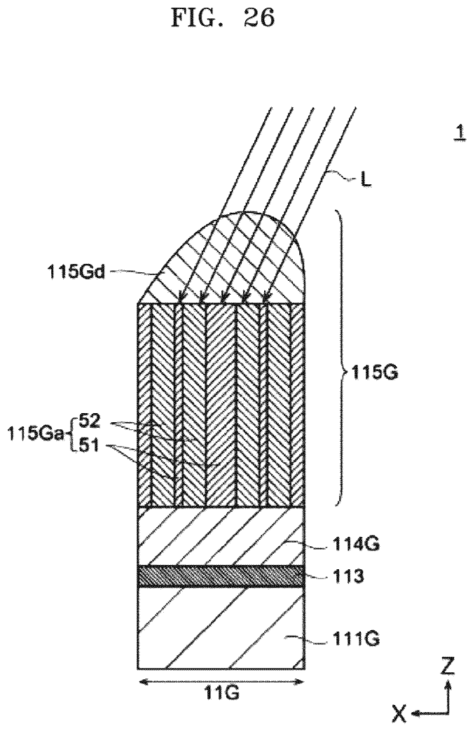

FIG. 26 is a diagram illustrating another example of a cross-sectional configuration of the image sensor 1 illustrated in FIG. 24. A green light collector 115G of the image sensor 1 may include a first layer 115Ga and an on-chip lens 115Gd stacked in a Z direction of the first layer 115Ga. For example, a convex shape of the on-chip lens 115Gd may be differently changed based on positions of the green pixels 11G of the pixel array 110.

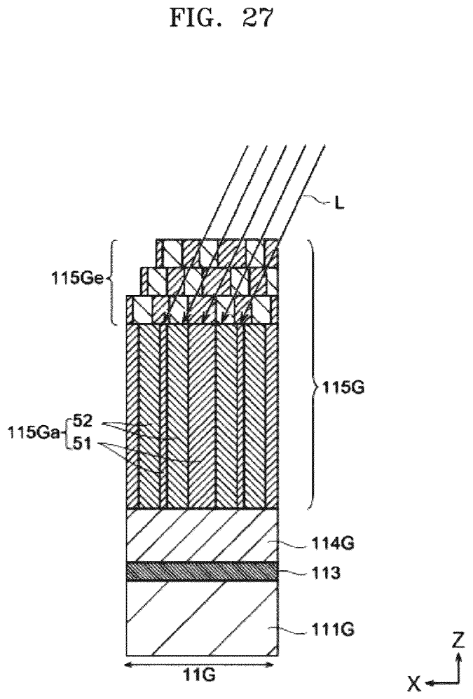

FIG. 27 is a diagram illustrating another example of a cross-sectional configuration of the image sensor 1 illustrated in FIG. 24. A green light collector 115G of the image sensor 1 may include a first layer 115Ga and a microlens array 115Ge stacked in a Z direction of the first layer 115Ga. For example, an array state of the microlens array 115Ge may be differently changed based on positions of the green pixels 11G of the pixel array 110.

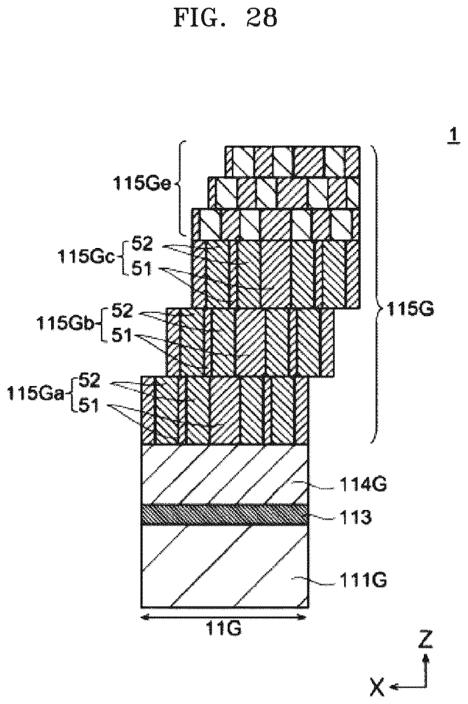

FIG. 28 is a diagram illustrating another example of a cross-sectional configuration of the image sensor 1 illustrated in FIG. 24. A green light collector 115G of the image sensor 1 may include a first layer 115Ga, a second layer 115Gb, a third layer 115Gc, and a microlens array 115Ge. The green light collector 115G may include the first layer 115Ga, the second layer 115Gb, and an on-chip lens 115Gd. The green light collector 115G may include all combinations of the first layer 115Ga, the second layer 115Gb, the third layer 115Gc, and the microlens array 115Ge.

In the image sensor 1, because the green light collector 115G has a stack structure, a light collection direction may be adjusted based on positions of the green pixels 11G of the pixel array 110. This may be identically applied to the red light collector 115R and the blue light collector 115B.

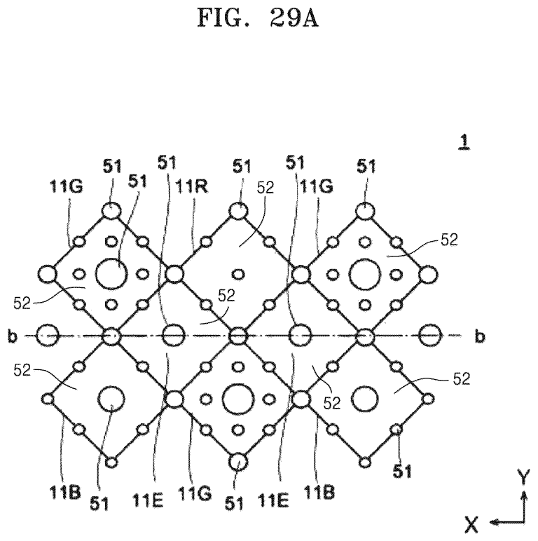

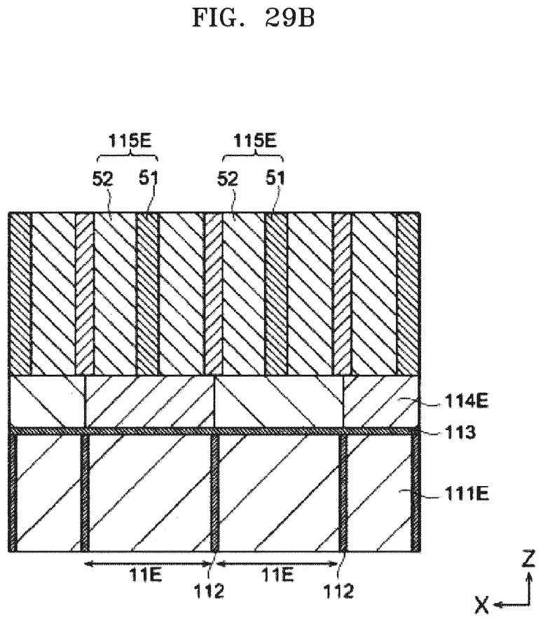

FIGS. 29A and 29B illustrate an example of a configuration of a main part of an image sensor 1 according to one or more embodiments. FIG. 29A illustrates an example of a plane configuration of each pixel 11. FIG. 29B illustrates an example of a cross-sectional configuration taken along line b-b illustrated in FIG. 29A. In an image sensor 1, a high refractive region 51 and a low refractive region 52 may be additionally disposed in a detection light collector 115E of a detection pixel 11E with a certain pattern. In this context, the image sensor 1 of FIGS. 29A and 29B may differ from the image sensor 1 according to the embodiment described above.

In the image sensor 1, in addition to a red light collector 115R, a green light collector 115G, and a blue light collector 115B, the high refractive region 51 and the low refractive region 52 may be disposed in the detection light collector 115E with a certain pattern. Accordingly, a light collection region may be formed all over a range which is wider than the detection light collector 115E, and thus, the sufficient amount of received light may be maintained in the detection pixel 11E.

According to another embodiment, a red pixel 11R, a green pixel 11G, a blue pixel 11B, and a detection pixel 11E may include a planar shape other than the embodiment described above.

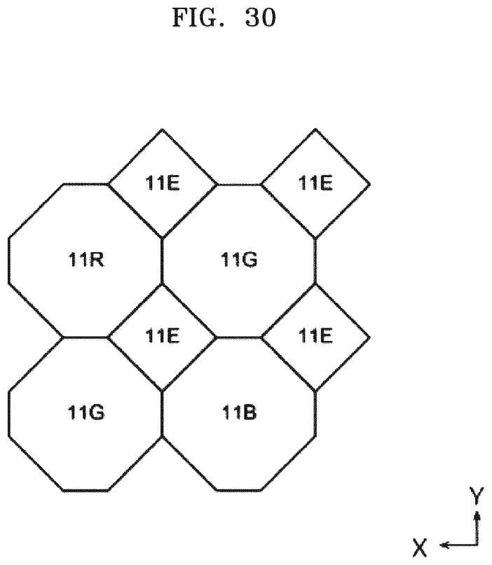

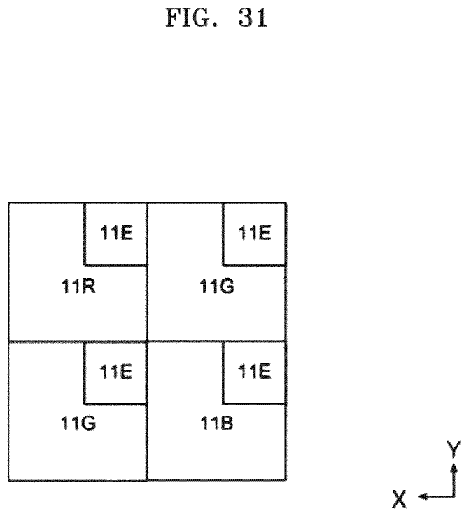

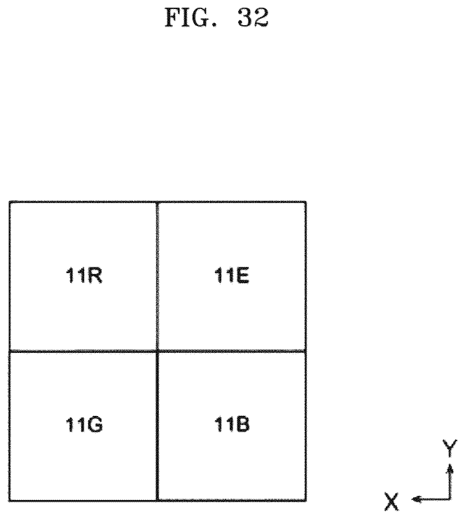

FIGS. 30, 31, and 32 illustrate another example of a planar shape of each pixel 11 illustrated in FIG. 2. For example, a red pixel 11R, a green pixel 11G, and a blue pixel 11B may include a polygonal shape which is greater than or equal to a pentagonal shape, and referring to FIG. 30, for example, may include an octagonal planar shape. Referring to FIG. 31, each of a red pixel 11R, a green pixel 11G, and a blue pixel 11B and a detection pixel 11E may include a tetragonal planar shape. Referring to FIGS. 30 and 31, a size of each of the red pixel 11R, the green pixel 11G, and the blue pixel 11B may be greater than that of the detection pixel 11E. Referring to FIG. 32, the number of red pixels 11R, green pixels 11G, and blue pixels 11B per unit area may be more than the number of detection pixels 11E.

For example, in an image sensor 1, an event signal output from a detection circuit 117 of each of a plurality of detection pixels 11E may be binning-processed.

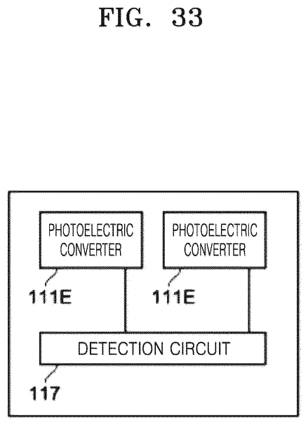

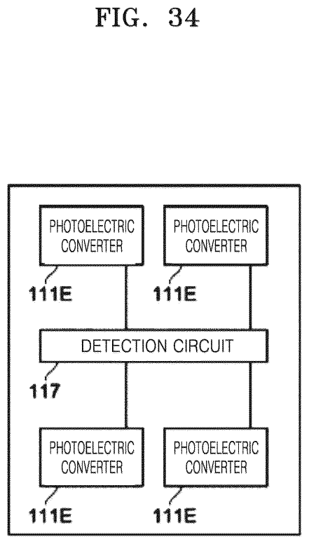

FIGS. 33 and 34 illustrate an example of a connection state between a detection circuit 117 and a detection photoelectric converter 111E of a detection pixel 11E. Referring to FIG. 33, for example, in the image sensor 1, electric charges accumulated in a floating diffusion FD of each of two detection photoelectric converters 111E may be added and binning-processed. Referring to FIG. 34, for example, in the image sensor 1, electric charges accumulated in a floating diffusion of each of four detection photoelectric converters 111E may be added and binning-processed. A sensitivity of the image sensor 1 may be enhanced by binning-processing an event signal output from a detection circuit 117 of each of a plurality of detection pixels 11E.

For example, a grayscale pixel of the image sensor 1 may include another element. For example, the grayscale pixel of the image sensor 1 may include a red pixel, a green pixel, a blue pixel, and a white pixel. Alternatively, the grayscale pixel of the image sensor 1 may include a cyan pixel, a magenta pixel, and a yellow pixel. As another alternative, the grayscale pixel of the image sensor 1 may include a red pixel, a yellow pixel, and a blue pixel.

In describing features of the embodiments described above, the main elements of the image sensor 1 have been described above, and the disclosure is not limited to the above descriptions and may be variously modified in claims. Also, a configuration where a general image sensor 1 is provided may not be excluded. For example, the number of pixels, the number of divisions of pixels, a layer distribution method of pixels, the number of stacks, and the number of divisions of bits of a counter (particularly, the number of divisions of upper bit groups and the number of arrangement stacks) may not be limited to content of embodiments.

For example, some of a plurality of embodiments may be combined. For example, an image sensor 1 may be configured by combining the embodiment of FIG. 17A and the embodiment of FIG. 29A.

At least one of the components, elements, modules, units, or the like (collectively “components” in this paragraph) represented by a block or an equivalent indication (collectively “block”) in the above embodiments including the drawings such as FIGS. 1, 4A, 4B, 33 and 34, for example, driver, arbiter, event signal processor, luminance signal processor, detector circuit, read circuit, photoelectric converter, light collector, or the like, may carry out the above-described function or functions. These blocks may be physically implemented by analog and/or digital circuits such as logic gates, integrated circuits, microprocessors, microcontrollers, memory circuits, passive electronic components, active electronic components, optical components, hardwired circuits and the like, and may optionally be driven by a firmware. The circuits may, for example, be embodied in one or more semiconductor chips, or on substrate supports such as printed circuit boards and the like. The circuits constituting a block may be implemented by dedicated hardware, or by a processor (e.g., one or more programmed microprocessors and associated circuitry), or by a combination of dedicated hardware to perform some functions of the block and a processor to perform other functions of the block. Each block of the embodiments may be physically separated into two or more interacting and discrete blocks without departing from the scope of the disclosure. Likewise, the blocks of the embodiments may be physically combined into more complex blocks without departing from the scope of the disclosure.

While the disclosure has been particularly shown and described with reference to embodiments thereof, it will be understood that various changes in form and details may be made therein without departing from the spirit and scope of the following claims.

1. An image sensor comprising:
a first grayscale pixel comprising a first photoelectric converter and a first light collector configured to allow light of a first wavelength range to be collected in the first photoelectric converter;
a detection pixel adjacent to the first grayscale pixel, the detection pixel comprising a detection photoelectric converter and a detection circuit configured to detect a variation of an amount of light incident on the detection photoelectric converter over time;
a high refractive region comprising a first refractive index; and
a low refractive region comprising a second refractive index,
wherein the second refractive index is less than the first refractive index, and
wherein the high refractive region and the low refractive region are in the first light collector and are arranged in a first pattern.

2. The image sensor of claim 1, further comprising a pillar-shaped structure extending in a stack direction of the first photoelectric converter and the first light collector,
wherein the pillar-shaped structure is in the high refractive region.

3. The image sensor of claim 2,
wherein the pillar-shaped structure is provided in plurality in the first light collector, and
wherein at least two of the plurality of pillar-shaped structures have different diameters.

4. The image sensor of claim 1, further comprising:
a second grayscale pixel at a position adjacent to the detection pixel, the second grayscale pixel comprising a second photoelectric converter and a second light collector configured to allow light of a second wavelength range, differing from the first wavelength range, to be collected in the second photoelectric converter,
wherein the high refractive region and the low refractive region are in the second light collector and are arranged in a second pattern which differs from the first pattern.

5. The image sensor of claim 4,
wherein the detection pixel further comprises a detection light collector adjacent to the first light collector,
wherein the first light collector and a first light collection region comprising at least a portion of the detection light collector is configured such that light of the first wavelength range incident on the first light collector and the first light collection region is incident on the first photoelectric converter, and
wherein the second light collector and a second light collection region including at least a portion of the detection light collector are configured such that light of the second wavelength range incident on the second light collector and the second light collection region is incident on the second photoelectric converter.

6. The image sensor of claim 5, wherein a size of the first light collection region differs from a size of the second light collection region.

7. The image sensor of claim 5, wherein the high refractive region and the low refractive region are in the detection light collector.

8. The image sensor of claim 5, wherein the detection pixel further comprises a detection color filter between the detection photoelectric converter and the detection light collector, and wherein the detection color filter is configured to selectively transmit light of a certain wavelength range.

9. The image sensor of claim 4, further comprising a third grayscale pixel at a position adjacent to the detection pixel, the third grayscale pixel comprising a third photoelectric converter and a third light collector configured to allow light of a third wavelength range, differing from the first wavelength range and the second wavelength range, to be collected in the third photoelectric converter,
wherein a total number of first grayscale pixels, second grayscale pixels, and third grayscale pixels included in a unit pixel group of the image sensor is equal to a total number of detection pixels included in the unit pixel group.

10. The image sensor of claim 4, wherein each of the first wavelength range and the second wavelength range comprises a wavelength range corresponding to visible light.

11. The image sensor of claim 1, further comprising a pixel array comprising a plurality of first grayscale pixels and a plurality of detection pixels each arranged at a certain pitch interval.

12. The image sensor of claim 11, wherein the high refractive region and the low refractive region are in the first light collector of each of the plurality of first grayscale pixels are arranged in a different pattern.

13. The image sensor of claim 12, wherein a symmetry of the high refractive region and the low refractive region differs in the first light collector of each of the plurality of first grayscale pixels.

14. The image sensor of claim 11,
wherein the first light collector comprises a first layer and a second layer stacked on the first layer,
wherein the first layer and the second layer are staggered by a certain amount of shift from an end of the first layer, and
wherein the high refractive region and the low refractive region are in each of the first layer and the second layer with a certain pattern.

15. The image sensor of claim 14, wherein the certain amount of shift between the first layer and the second layer differs in the first light collector of each of the plurality of first grayscale pixels.

16. (canceled)

17. The image sensor of claim 1, wherein the first grayscale pixel further comprises a first color filter between the first photoelectric converter and the first light collector, and wherein the first color filter is configured to selectively transmit light of the first wavelength range.

18. The image sensor of claim 1, wherein a size of the first grayscale pixel is greater than or equal to a size of the detection pixel.

19. An image sensor comprising:
a first grayscale pixel;
a second grayscale pixel;
a third grayscale pixel; and
a detection pixel adjacent to the first grayscale pixel, the second grayscale pixel, and the third grayscale pixel,
wherein the first grayscale pixel comprises a first light collector configured to allow light of a first wavelength range to be collected in a first photoelectric converter,
wherein the second grayscale pixel comprises a second light collector configured to allow light of a second wavelength range to be collected in a second photoelectric converter,
wherein the third grayscale pixel comprises a third light collector configured to allow light of a third wavelength range to be collected in a third photoelectric converter, and
wherein each of the first light collector, the second light collector, and the third light collector comprises a high refractive region and a low refractive region arranged in a certain pattern and having a refractive index which is less than a refractive index of the high refractive region.

20. The image sensor of claim 19, wherein a first pattern of the high refractive region and the low refractive region in the first light collector, a second pattern of the high refractive region and the low refractive region in the second light collector, and a third pattern of the high refractive region and the low refractive region in the third light collector are different from one another.

21. An image sensor comprising:
a pixel array comprising a center portion, a peripheral portion surrounding the center portion, and an end portion corresponding to an outer portion of the peripheral portion, the pixel array further comprising a plurality of pixels,
wherein each of the plurality of pixels comprises a light collector configured to collect light,
wherein a light collector in the center portion comprises a first pattern comprising a high refractive region comprising a first refractive index and a low refractive region comprising a second refractive index which is less than the first refractive index,
wherein a light collector in the peripheral portion comprises a second pattern comprising a high refractive region comprising a third refractive index and a low refractive region comprising a fourth refractive index which is less than the third refractive index,
wherein a light collector in the end portion comprises a third pattern comprising a high refractive region comprising a fifth refractive index and a low refractive region comprising a sixth refractive index which is less than the fifth refractive index, and
wherein the first pattern, the second pattern, and the third pattern differ.
